(19) United States
(12) Patent Application Publication
(10) Pub. No.: US 2025/0048806 A1
(43) Pub. Date: Feb. 6, 2025

(54) DISPLAY DEVICE AND METHOD OF MANUFACTURING THE SAME

(71) Applicant: Samsung Display Co., Ltd., Yongin-Si (KR)

(72) Inventors: Kyu Ho JUNG, Yongin-si (KR); Sang Chul BYUN, Yongin-si (KR); Soo Yeon HAN, Yongin-si (KR)

(21) Appl. No.: 18/788,138

(22) Filed: Jul. 30, 2024

(30) Foreign Application Priority Data
Jul. 31, 2023 (KR) 10-2023-0100091

(51) Int. Cl. H01L 33/56; H01L 25/075; H01L 25/16; H01L 33/62

(52) U.S. Cl. CPC H01L 33/56; H01L 25/0753; H01L 25/167; H01L 33/62; H01L 2933/005

(57) ABSTRACT

According to an embodiment of the disclosure, a display device may include a substrate where a display area and a non-display area are defined, the non-display area including a pad area, a display part disposed on the substrate and displaying an image, a pad part disposed in the pad area and including a plurality of pads, a dam positioned between the pad part and the display part and surrounding at least one side of the display part, and a filling layer disposed on the display part surrounded by the dam to cover the display part. The filling layer may include a transparent curable resin and is positioned in an uppermost layer in the display area.

This application claims priority to Korean Patent Application No. 10-2023-0100091, filed on Jul. 31, 2023, and all the benefits accruing therefrom under 35 U.S.C. § 119, the content of which in its entirety is herein incorporated by reference.

### BACKGROUND

### 1. Field

The disclosure relates to a display device and a method of manufacturing the same.

### 2. Description of the Related Art

Recently, as interest in an information display is increased, research and development on a display device are being continuously conducted.

### SUMMARY

The disclosure may provide a display device and a method of manufacturing the same with improved manufacturing efficiency and reliability.

According to an embodiment of the disclosure, a display device may include a substrate where a display area and a non-display area are defined, the non-display area including a pad area, a display part including the substrate and displaying an image, a pad part disposed in the pad area and including a plurality of pads, a dam positioned between the pad part and the display part and surrounding at least one side of the display part, and a filling layer disposed on the display part surrounded by the dam to cover the display part. The filling layer may include a transparent curable resin and is positioned in an uppermost layer in the display area.

In an embodiment, the filling layer may include at least one of epoxy and silicone. The dam may include a siloxane-based resin.

In an embodiment, the dam may have a width of about 0.5 mm to 5 mm.

In an embodiment, the dam may include a curable resin of which a viscosity is higher than a viscosity of the filling layer.

In an embodiment, the dam and the filling layer may include a curable resin of which a viscosity is the same.

In an embodiment, the substrate may include a silicon wafer substrate.

In an embodiment, the display part may include a pixel circuit layer disposed on the substrate, a light emitting element layer including a light emitting element, the light emitting element configured of a first electrode disposed on the pixel circuit layer, a light emitting layer disposed on the first electrode, and a second electrode disposed on the light emitting layer, and a thin film encapsulation layer disposed between the light emitting element layer and the filling layer.

In an embodiment, the display part may further include an optical layer disposed between the thin film encapsulation layer and the filling layer.

In an embodiment, the dam may have a pencil hardness of 7H or more, and the filling layer may have a pencil hardness of 4H or more.

According to an embodiment of the disclosure, a method of manufacturing a display device may include preparing a mother substrate including a first display cell group and a second display cell group including first display cells and second display cells, respectively, and a cutting line of a shape corresponding to each of the first and second display cells. A dam is formed surrounding a display part of the first and second display cells. A filling layer is formed on the display part surrounded by the dam. The first and second display cells are individually separating by cutting the mother substrate by irradiating a laser beam. The first display cell group and the second display cell group are symmetrical with respect to the cutting line between the first display cell group and the second display cell group.

In an embodiment, each of the first and second display cells may include the display part and a pad part positioned around the display part. The display part may include a pixel circuit layer disposed on the mother substrate, and a light emitting element layer including a light emitting element, the light emitting element configured of a first electrode disposed on the pixel circuit layer, a light emitting layer disposed on the first electrode, and a second electrode disposed on the light emitting layer.

In an embodiment, in a plan view, the display part of each of the first display cells and the display part of each of the second display cells in each of the first and second display cell groups may face each other in a column direction of the mother substrate.

In an embodiment, in each of the first and second display cells, the dam may be positioned between the display part and the pad part.

In an embodiment, in each of the first and second display cell groups, the dam may be coated and then cured to be formed along at least one outer periphery of the display part of each of the first and second display cells.

In an embodiment, in each of the first and second display cell groups, the filling layer may be coated and then cured to fill an inside of one area of the mother substrate surrounded by the dam.

In an embodiment, in a plan view, the pad part of each of the second display cells of the first display cell group and the pad part of each of the first display cells of the second display cell group may face each other in a column direction of the mother substrate.

In an embodiment, the filling layer may include at least one of epoxy and silicone. The dam may include a siloxane-based resin.

In an embodiment, the dam may include a curable resin of which a viscosity is higher than a viscosity of the filling layer.

In an embodiment, the dam and the filling layer may include a curable resin of which a viscosity is the same.

In an embodiment, the dam may be applied and then directly cured to be formed along at least one outer periphery of the display part of each of the first and second display cells.

According to an embodiment, the dam formed of the curable resin having a viscosity of a certain level or higher is formed on the mother substrate including the first display cell group and the second display cell group to surround one area of each of the first and second display cell groups. In addition, a space surrounded by the dam may be filled with the filling layer formed of the curable resin having a viscosity of a certain level or higher.

According to an embodiment, the mother substrate may be easily separated by securing sufficient support strength equivalent to that of encapsulation glass (or cover glass) during laser cutting while protecting display cells of each of the first and second display cell groups using the dam and the filling layer formed to have a firm hardness by applying a coating liquid formed of a curable resin with a viscosity of a certain level or higher and then curing the coating liquid.

Accordingly, a display device with improved manufacturing efficiency may be provided by omitting a process of forming the encapsulation glass and a process of cutting the encapsulation glass.

An effect according to an embodiment is not limited by the contents exemplified above, and more various effects are included in the present specification.

### BRIEF DESCRIPTION OF THE DRAWINGS

FIG. 1 is a schematic plan view illustrating a mother substrate according to an embodiment.

FIG. 2 is a schematic enlarged view showing an EA portion of FIG. 1.

FIG. 3 is a schematic cross-sectional view taken along a line I-I′ of FIG. 2.

FIG. 4 is a schematic cross-sectional view taken along a line II-II′ of FIG. 2.

FIG. 5 is a schematic plan view showing a display device according to an embodiment.

FIG. 6 is a schematic cross-sectional view showing a display panel according to an embodiment.

FIG. 7 is a schematic exploded perspective view showing a display panel according to an embodiment.

FIG. 8 is a schematic circuit diagram illustrating an electrical connection relationship of components included in each of pixels shown in FIG. 5.

FIGS. 9A, 9B, 9C, and 9D are schematic cross-sectional views taken along a line III-III′ of FIG. 5.

FIG. 9E is a schematic diagram showing a light emitting layer of FIG. 9A.

FIGS. 10A, 10B, 10C, 10D, and 10E are schematic plan views corresponding to an EA portion of FIG. 1 sequentially illustrating a method of manufacturing a display device according to an embodiment.

FIG. 11A is a schematic cross-sectional view taken along a line IV-IV′ of FIG. 10A.

FIG. 11B is a schematic cross-sectional view taken along the line IV-IV′ of FIG. 10B.

FIG. 11C is a schematic cross-sectional view taken along the line IV-IV′ of FIG. 10C.

FIG. 11D is a schematic cross-sectional view taken along the line IV-IV′ of FIG. 10D.

FIG. 11E is a schematic cross-sectional view taken along the line IV-IV′ of FIG. 10E.

FIG. 12 is a schematic cross-sectional view corresponding to the line I-I′ of FIG. 2 illustrating a mother substrate according to an embodiment.

FIG. 13 is a schematic cross-sectional view corresponding to the line I-I′ of FIG. 2 illustrating a mother substrate according to an embodiment.

FIGS. 14A and 14B are schematic cross-sectional views illustrating a manufacturing method of forming a dam of FIG. 13.

### DETAILED DESCRIPTION OF THE EMBODIMENT

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the technical scope of the disclosure.

Similar reference numerals are used for similar components in describing each drawing. In the accompanying drawings, the dimensions of the structures are shown enlarged from the actual dimensions for the sake of clarity of the disclosure. Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a film, an area, a plate, or the like is referred to as being “on” another portion, it includes not only a case where the portion is “directly on” another portion, but also a case where there is further another portion between the portion and another portion. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion.

Hereinafter, embodiments of the disclosure and others necessary for those skilled in the art to understand the disclosure will be described in detail with reference to the accompanying drawings. In the following description, the singular expressions include plural expressions unless the context clearly dictates otherwise.

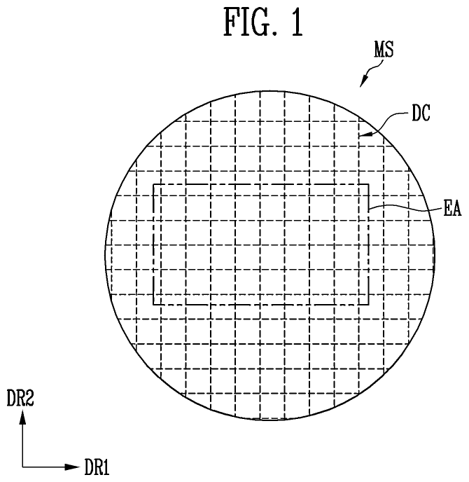

FIG. 1 is a schematic plan view illustrating a mother substrate MS according to an embodiment.

Referring to FIG. 1, the mother substrate MS may be a substrate for simultaneously manufacturing a plurality of display cells DC for process convenience. The mother substrate MS may include at least one unit area. A unit area may be a portion corresponding to an individual display cell DC (or an individual display device), and the individual display cell DC may be formed in each unit area.

In an embodiment, the mother substrate MS may be a silicon wafer substrate formed using a semiconductor process. For example, the mother substrate MS may include a semiconductor material, for example, a Group IV semiconductor, a III-V compound semiconductor, or a II-VI compound semiconductor, but is not limited thereto. According to an embodiment, the mother substrate MS may include a transparent insulating material capable of transmitting light. For example, the mother substrate MS may be a rigid substrate or a flexible substrate. The rigid substrate may be, for example, one of a glass substrate, a quartz substrate, a glass ceramic substrate, and a crystalline glass substrate. The flexible substrate may be one of a film substrate and a plastic substrate including a polymeric organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, triacetate cellulose, and cellulose acetate propionate.

Each display cell DC may be individually separated to serve as a display device, and may be separated through a cutting process after forming the plurality of display cells DC simultaneously on the mother substrate MS. The display cells DC may be provided in plurality on the mother substrate MS, and may be arranged in a matrix form along a row (or a display cell row) extending in a first direction DR1 and a column (or a display cell column) extending in a second direction DR2, but are not limited thereto.

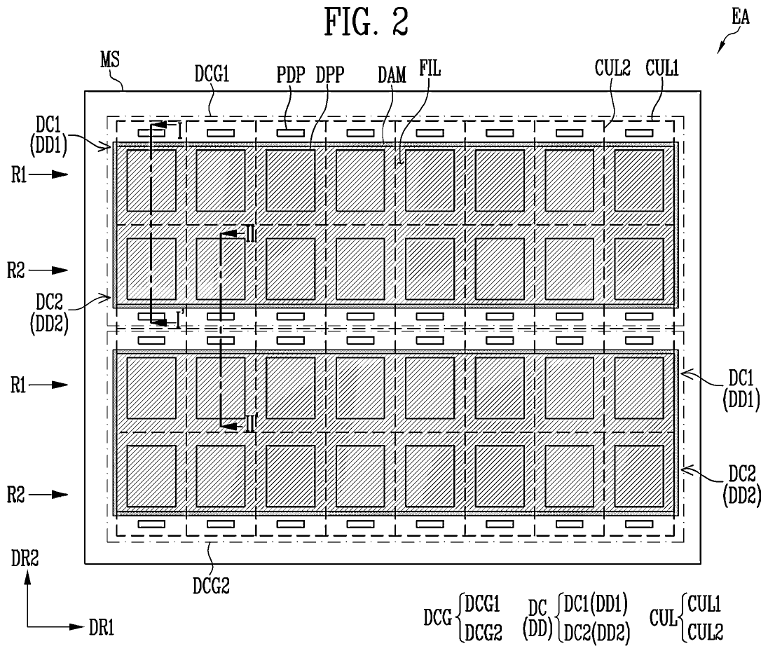

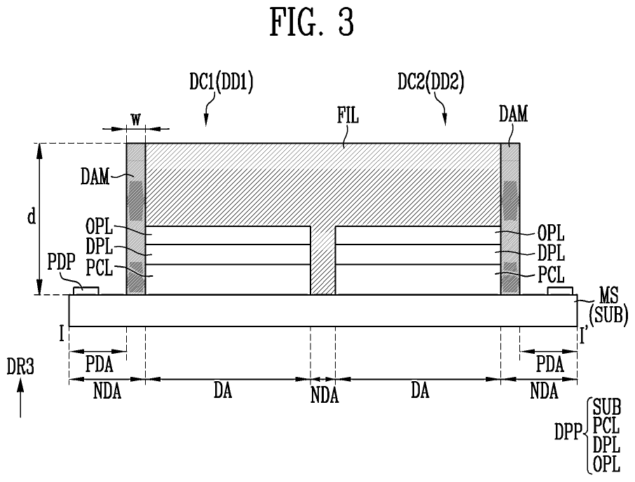

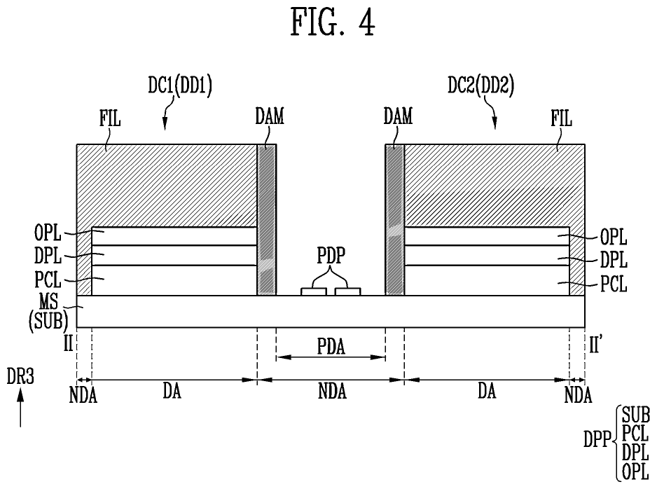

FIG. 2 is a schematic enlarged view showing an EA portion of FIG. 1. FIG. 3 is a schematic cross-sectional view taken along a line I-I′ of FIG. 2. FIG. 4 is a schematic cross-sectional view taken along a line II-II′ of FIG. 2.

Referring to FIGS. 1 to 4, a cutting line CUL corresponding to each of the display cells DC (or display devices DD) may be provided in the mother substrate MS. The cutting line CUL may include a first cutting line CUL1 extending in the first direction DR1 and a second cutting line CUL2 extending in the second direction DR2. Each of the display cells DC (or the display devices DD) may be individually separated through a process of cutting the mother substrate MS along the cutting line CUL using a laser beam.

The mother substrate MS may be a substrate SUB, which is a base material of the corresponding display cell DC after the display cells DC are individually separated.

Each of the display cells DC may include a display part DPP and a pad part PDP. The display part DPP may be positioned in a display area DA, and the pad part PDP may be positioned in one area of a non-display area NDA, for example, a pad area PDA.

The display part DPP may include the substrate SUB, a pixel circuit layer PCL, a display element layer DPL, and an optical layer OPL (or a micro lens array). The optical layer OPL may be selectively provided.

The substrate SUB may be one area of the mother substrate MS and may be a silicon wafer substrate. The substrate SUB may include the display area DA where an image is displayed and the non-display area NDA where an image is not displayed.

The pixel circuit layer PCL may be disposed on the substrate SUB and may include circuit elements.

The display element layer DPL may be disposed on the pixel circuit layer PCL and may include a light emitting element layer including a light emitting element and a thin film encapsulation layer disposed on the light emitting element layer.

The optical layer OPL may be disposed on the display element layer DPL, and may include a micro lens array for improving extraction efficiency of light emitted from the display element layer DPL, but is not limited thereto.

In an embodiment, a first display cell group DCG1 and a second display cell group DCG2 alternately arranged in the second direction DR2 (or a column direction) may be defined in the mother substrate MS. For example, the first display cell group DCG1, the second display cell group DCG2, the first display cell group DCG1, the second display cell group DCG2, and . . . may be sequentially arranged.

Each of the first display cell group DCG1 and the second display cell group DCG2 may include a first row R1 (for example, a first display cell row) and a second row R2 (for example, a second display cell row) extending in the first direction DR1. A plurality of first display cells DC1 (or a first display device DD1) may be arranged in the first row R1, and a plurality of second display cells DC2 (or a second display device DD2) may be arranged in the second row R2.

Each of the first display cells DC1 and the second display cells DC2 may include the display part DPP and the pad part PDP. An external connection terminal may be coupled to the pad part PDP after a process of separating the mother substrate MS in a unit of the display cell DC. The display cell DC may be electrically connected to an outside by the external connection terminal coupled to the pad part PDP.

In each of the first display cell group DCG1 and the second display cell group DCG2, the display part DPP may be positioned adjacent to the first cutting line CUL1 positioned between the first display cells DC1 and the second display cells DC2. For example, in each of the first display cell group DCG1 and the second display cell group DCG2, the display part DPP of the first display cells DC1 and the display part DPP of the second display cells DC2 may be positioned adjacent to the first cutting line CUL1 positioned between the first display cells DC1 and the second display cells DC2. In this case, in a plan view, the display part DPP of each of the first display cells DC1 and the display part DPP of each of the second display cells DC2 face each other in the second direction DR2 (or the column direction).

In addition, in each of the first display cell group DCG1 and the second display cell group DCG2, the pad part PDP may be positioned away from the first cutting line CUL1 positioned between the first display cells DC1 and the second display cells DC2 than the display part DPP included in the corresponding display cell group DCG. For example, the pad part PDP may be positioned outside the display part DPP based on the first cutting line CUL1.

Two display cell groups DCG adjacent in the second direction DR2 may be symmetrical with respect to the first cutting line CUL1 positioned between two display cell groups DCG. For example, the first display cell group DCG1 and the second display cell group DCG2 may be symmetrical with respect to the first cutting line CUL1 positioned between the first display cell group DCG1 and the second display cell group DCG2. In the two display cell groups DCG, the pad part PDP of the second display cells DC2 of a preceding display cell group DCG and the pad part PDP of the first display cells DC1 of a subsequent display cell group DCG may face each other based on the first cutting line CUL1 positioned between the two display cell groups DCG. For example, the pad part PDP of the second display cells DC2 of the first display cell group DCG1 and the pad part PDP of the first display cells DC1 of the second display cell group DCG2 may face each other based on the first cutting line CUL1 positioned between the first display cell group DCG1 and the second display cell group DCG2.

A dam DAM may be formed in each of the first display cell group DCG1 and the second display cell group DCG2.

The dam DAM may be disposed in a form surrounding at least one side of the display parts DPP in each display cell group DCG. The dam DAM may be disposed in a form surrounding at least one side of the display parts DPP to include all display parts DPP included in each display cell group DCG. The dam DAM may be positioned between the display part DPP and the pad part PDP in the non-display area NDA of each display cell DC. In an embodiment, the dam DAM may be configured by including a curable resin having a viscosity of a certain level or higher. In an embodiment, the viscosity of the certain level or higher may mean a high viscosity within a range, in which when a first coating liquid corresponding to a base material of the dam DAM is applied to a predetermined application area (or a targeted area), the first coating liquid may be stably fixed in the predetermined application area without flowing or moving. For example, the dam DAM may be configured by including a siloxane-based resin. The siloxane-based resin may have, for example, a viscosity (cps) of about 70,000 to about 270,000 and have a pencil hardness of 7H or more after being cured. In addition, the siloxane-based resin may have a light transmittance of about 94.34%. However, a material property of the siloxane-based resin is not limited to the above-described embodiment.

For example, the dam DAM may have a thickness d of 600 μm or less in a third direction DR3, e.g., perpendicular to the first and second directions DR1, DR2, and may have a width w of about 2 mm in a direction parallel to a main surface (or an upper surface) of the mother substrate MS (or substrate SUB), e.g., in a plane defined by the first and second directions DR1, DR2, but the dam DAM is not limited thereto. According to an embodiment, the dam DAM may have a width w of about 0.5 mm to about 5 mm in the direction parallel to the main surface of the mother substrate MS (or substrate SUB). The width w of the dam DAM may be determined within a range in which the first coating liquid applied between the display part DPP and the pad part PDP of each display cell DC does not invade each of the display part DPP and the pad part PDP.

The dam DAM may be a structure that stably fixes and supports a filling layer FIL and each display part DPP while defining a supply position of the filling layer FIL. In addition, the dam DAM may be a reinforcing member that improves mechanical strength of the mother substrate MS together with the filling layer FIL cured through a curing process. In addition, the dam DAM may control a flow of a monomer of the thin film encapsulation layer included in the display part DPP to define a formation position of the monomer.

The filling layer FIL may be formed inside one area of each of the first and second display cell groups DCG1 and DCG2 surrounded by the dam DAM. The filling layer FIL may be provided in a form of filling an area of each of the first and second display cell groups DCG1 and DCG2 surrounded by the dam DAM. The filling layer FIL may be disposed on the display part DPP of the display cells DC of each of the first and second display cell groups DCG1 and DCG2 to cover the display part DPP. The filling layer FIL may include a curable resin having a viscosity of a certain level or higher. For example, the filling layer FIL may be configured by including an epoxy-based resin or a silicon-based resin. The epoxy-based resin may have, for example, a viscosity (cps) of about 19 to about 5,400 and may have a pencil hardness of 4H or more after being cured. In addition, the epoxy-based resin may have a light transmittance of about 92.65%. However, a material property of the epoxy-based resin is not limited to the above-described embodiment. The filling layer FIL may include a curable resin of which a viscosity is lower than that of the dam DAM, but is not limited thereto. According to an embodiment, the filling layer FIL may include a curable resin having the same viscosity as that of the dam DAM.

In each of the first display cell group DCG1 and the second display cell group DCG2, after applying a second coating liquid corresponding to a base material of the filling layer FIL in an area surrounded by the dam DAM, a curing process using light may be performed to finally form the filling layer FIL in the display cells DC. The filling layer FIL may be cured and fixed by performing a curing process after being coated while filling an inside of one area of each of the first and second display cell groups DCG1 and DCG2 surrounded by the dam DAM.

In the display area DA of each display cell DC, the filling layer FIL may be positioned as an uppermost layer. That is, the filling layer FIL may be positioned at the uppermost layer in the display area DA of each display cell DC to entirely cover configurations positioned thereunder. In an embodiment, the filling layer FIL may protect each display cell DC from external impact or the like and may provide an input surface and/or a display surface to a user. The filling layer FIL may be a cover member.

According to the above-described embodiment, after forming the filling layer FIL including a curable resin having a viscosity of a certain level or higher in one area of each of the first and second display cell groups DCG1 and DCG2 surrounded by the dam DAM including the curable resin of high viscosity, the mother substrate MS is cut along the cutting line CUL using a laser beam, and thus each display cell DC (or display device DD) may be finally formed.

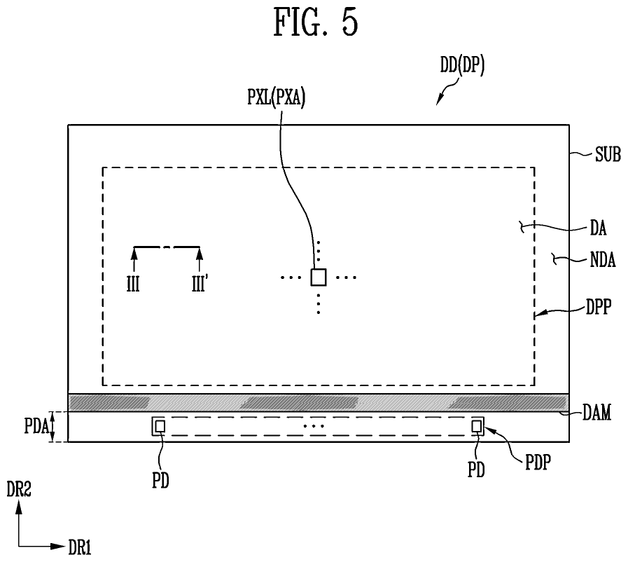

FIG. 5 is a schematic plan view showing a display device DD according to an embodiment.

The display device DD of FIG. 5 may be one display cell (refer to “DC” of FIG. 2) individually separated from the mother substrate (refer to “MS” of FIG. 2).

In FIG. 5, for convenience, a structure of a display device DD, for example, a display panel DP provided in the display device DD, is briefly shown based on the display area DA where an image is displayed.

Referring to FIGS. 1 to 5, the display device DD (or the display panel DP) according to an embodiment may include the substrate SUB, pixels PXL provided on the substrate SUB, a driving part that drives the pixels PXL, and a line component that electrically connects the pixels PXL and the driving part.

The substrate SUB may include a semiconductor substrate. For example, the substrate SUB may include a silicon bulk wafer or an epitaxial wafer. The epitaxial wafer may include a crystalline material layer grown by an epitaxial process on a bulk substrate, that is, an epitaxial layer. The substrate SUB is not limited to a silicon bulk wafer or an epitaxial wafer, and may be formed using various wafers such as a polished wafer, an annealed wafer, and a silicon on insulator (SOI) wafer. However, the disclosure is not limited thereto, and according to an embodiment, the substrate SUB may include a transparent insulating material capable of transmitting light. The substrate SUB may be one area of the mother substrate MS.

One area of the substrate SUB may be provided as the display area DA, where the display part DPP including the pixels PXL is disposed, and a remaining area of the substrate SUB may be provided as the non-display area NDA. For example, the substrate SUB may include a display area DA in which pixel areas PXA in which each pixel PXL is disposed are defined, and the non-display area NDA disposed around the display area DA (or adjacent to the display area DA).

The non-display area NDA may be provided on at least one side of the display area DA. The non-display area NDA may surround a circumference (or an edge) of the display area DA. The line component and the driving part may be disposed in the non-display area NDA. For example, the non-display area NDA may be an area where fan-out lines, pads PD, and/or an embedded circuit part electrically connected to the pixels PXL are/is disposed to drive the pixels PXL.

The non-display area NDA may include the pad area PDA. The pad area PDA may be an area of the non-display area NDA where the pad part PDP is positioned, and may be positioned closest to an edge (or a border) of the non-display area NDA. According to an embodiment, the non-display area NDA may include an anti-static circuit area where an anti-static circuit electrically connected to signal lines positioned in the display area DA to prevent generation of static electricity is positioned.

The pad part PDP may include a plurality of pads PD. The pads PD may supply driving power and signals for driving the pixels PXL and/or the embedded circuit part disposed in the display area DA. The pads PD may be electrically connected to an external circuit board through a conductive adhesive member or the like.

Each of the pixels PXL may be disposed in the pixel area PXA. The pixels PXL may be arranged in the display area DA in a stripe arrangement structure or the like, but are not limited thereto.

In an embodiment, the dam DAM may be positioned in the non-display area NDA of the substrate SUB. The dam DAM may define a supply position of the filling layer FIL formed in one area of each display cell DC provided in the mother substrate MS. In addition, the dam DAM may be a reinforcing member that improves mechanical strength of the mother substrate MS (or display cell DC) in a process of individually separating the mother substrate MS in a unit of the display cell DC by stably fixing the filling layer FIL. The dam DAM may include a light-blocking material in order to prevent visibility of configurations positioned thereunder, for example, the fan-out lines, and may be configured of a curable resin having a viscosity of a certain level or higher, but is not limited thereto.

The dam DAM may be positioned on at least one side of the display device DD. The dam DAM may be positioned between the display part DPP and the pad part PDP in one area of the non-display area NDA. The dam DAM may be applied to a targeted area so as not to overlap each of the display part DPP and the pad part PDP, and then cured.

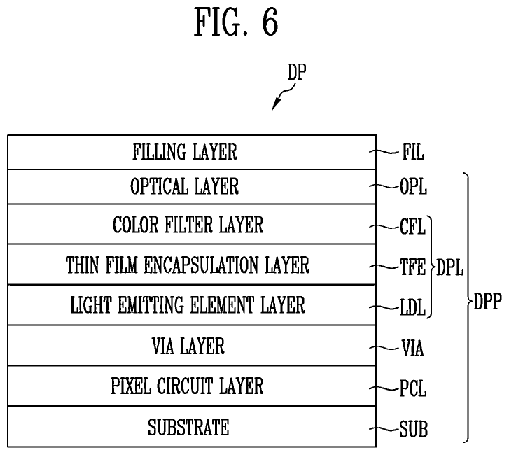

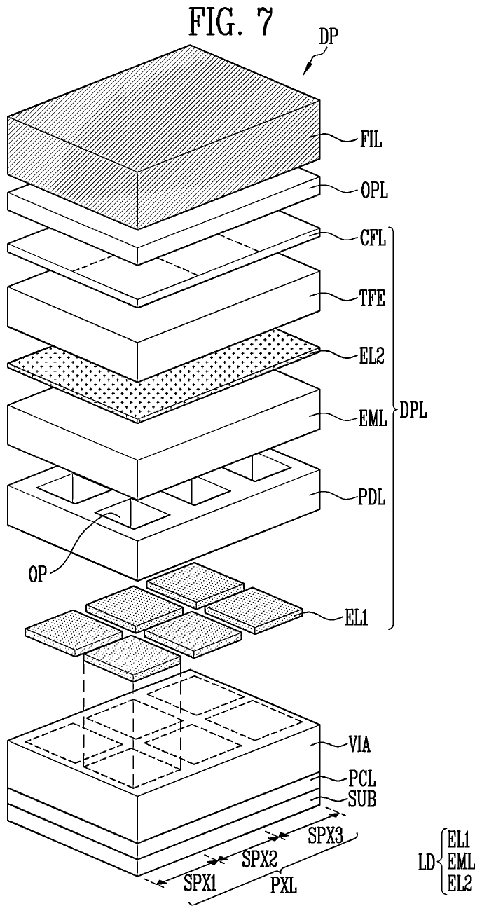

FIG. 6 is a schematic cross-sectional view of a display panel DP according to an embodiment. FIG. 7 is a schematic exploded perspective view showing a display panel DP according to an embodiment.

Referring to FIGS. 5 to 7, the display panel DP may include a plurality of pixels PXL.

Each of the pixels PXL may include a plurality of sub-pixels SPX1, SPX2, and SPX3. For example, each pixel PXL may include a first sub-pixel SPX1, a second sub-pixel SPX2, and a third sub-pixel SPX3 arranged adjacent to each other, but is not limited thereto. According to an embodiment, each pixel PXL may include four sub-pixels or two sub-pixels.

The display panel DP may include the display part DPP and the filling layer FIL covering the display part DPP. The display part DPP may include the substrate SUB, and the pixel circuit layer PCL, a via layer VIA, the display element layer DPL, and an optical layer OPL sequentially disposed on the substrate SUB.

The substrate SUB may include a semiconductor substrate. For example, the substrate SUB may include a silicon bulk wafer or an epitaxial wafer.

The pixel circuit layer PCL may be disposed on the substrate SUB, and may include circuit elements and at least one insulating layer positioned between the circuit elements. The circuit elements may include a plurality of transistors and signal lines connected to the transistors. As an example, the transistor may be a MOSFET, but is not limited thereto. The circuit elements may include, for example, a gate electrode, source/drain areas, and a channel area.

The via layer VIA may be selectively disposed on the pixel circuit layer PCL. The via layer VIA may be disposed on the pixel circuit layer PCL to cover the pixel circuit layer PCL. The via layer VIA may be selectively provided according to a material of the substrate SUB. For example, when the substrate SUB is a silicon wafer substrate, the via layer VIA may have a resonance structure to further improve extraction efficiency of light emitted from a light emitting element layer LDL. In this case, the via layer VIA may be partially opened to include a via hole, and the circuit element of the pixel circuit layer PCL and a first electrode EL1 of the light emitting element layer LDL may be electrically connected.

The display element layer DPL may be disposed on the via layer VIA. The display element layer DPL may include the light emitting element layer LDL, a thin film encapsulation layer TFE, and a color filter layer CFL.

The light emitting element layer LDL may include a light emitting element LD and a pixel defining layer PDL. The light emitting element LD may be disposed in each of the first, second, and third sub-pixels SPX1, SPX2, and SPX3. The light emitting element LD may include the first electrode EL1, a light emitting layer EML, and a second electrode EL2. The first electrode EL1 may be an anode of the light emitting element LD, and the second electrode EL2 may be a cathode of the light emitting element LD.

A hole injected from the first electrode EL1 and an electron injected from the second electrode EL2 of each of the first, second, and third sub-pixels SPX1, SPX2, and SPX3 may be transported into the light emitting layer EML to form an exciton, and when the exciton transits from an excited state to a ground state, light may be generated and may be emitted in a form of visible light.

The first electrode EL1 may be disposed on the via layer VIA. The first electrode EL1 may include a transparent conductive material capable of transmitting light and/or an opaque conductive material having reflectance capable of reflecting light.

The pixel defining layer PDL may be positioned on the first electrode EL1. The pixel defining layer PDL may include an opening OP exposing one area of the first electrode EL1.

The light emitting layer EML may be positioned on the first electrode EL1 exposed by the opening OP of the pixel defining layer PDL. In addition, the light emitting layer EML may be positioned on a side surface and an upper surface of the pixel defining layer PDL. The light emitting layer EML may be a common layer commonly provided to the first, second, and third sub-pixels SPX1, SPX2, and SPX3, but is not limited thereto. The light emitting layer EML may include a light generation layer emitting light, an electron transport layer, a hole transport layer, and the like.

The second electrode EL2 may be positioned on the light emitting layer EML to cover the light emitting layer EML. The second electrode EL2 may be a common layer commonly provided to the first, second, and third sub-pixels SPX1, SPX2, and SPX3.

The thin film encapsulation layer TFE may be positioned on the second electrode EL2. The thin film encapsulation layer TFE may cover the second electrode EL2 to prevent penetration of oxygen and/or moisture into the light emitting element LD.

The color filter layer CFL may be positioned on the thin film encapsulation layer TFE. The color filter layer CFL may selectively transmit light emitted from the light emitting element LD in an image display direction (or a front surface direction) of the display device DD. The color filter layer CFL may be selectively provided according to a type of the light emitting layer EML. For example, in case that the light emitting layer EML is commonly provided to the first, second, and third sub-pixels SPX1, SPX2, and SPX3 to emit white light, the color filter layer CFL may be disposed on the thin film encapsulation layer TFE to selectively transmit light of a specific wavelength range of the white light. According to an embodiment, in case that the light emitting layer EML is individually provided to the first, second, and third sub-pixels SPX1, SPX2, and SPX3 to emit light of different colors, the color filter layer CFL may be omitted.

The optical layer OPL may be disposed on the color filter layer CFL. The optical layer OPL may include a micro lens array that improves light extraction effect by changing a proceeding angle of the light emitted from the light emitting element layer LDL by forming a micro lens of a specific shape, such as a hemispherical shape, on a surface of the display element layer DPL, but is not limited thereto.

The filling layer FIL may be disposed on the optical layer OPL. The filling layer FIL may be disposed on the display part DPP to provide a display surface of the display device DD (or the display panel DP). The filling layer FIL may be a configuration disposed on the uppermost layer in the display area DA, and may protect the display part DPP from external impact or the like. The filling layer FIL may be configured by including a transparent curable resin having a viscosity higher of a certain level or higher.

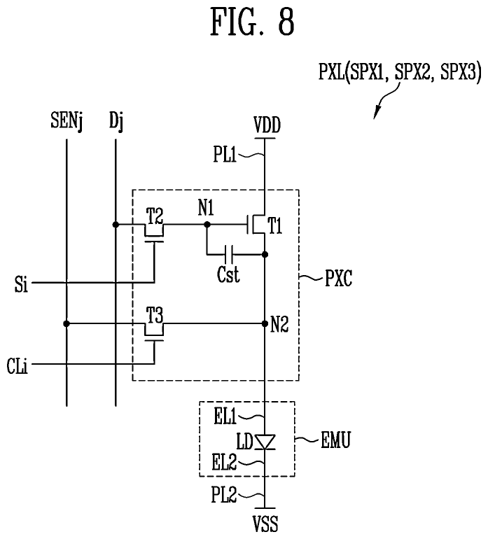

FIG. 8 is a schematic circuit diagram illustrating an electrical connection relationship of components included in each of the pixels PXL shown in FIG. 5.

In FIG. 8, for convenience, a pixel PXL positioned in an i-th pixel row (or an i-th horizontal line) and a j-th pixel column is shown, where i and j are natural numbers.

Referring to FIGS. 5 to 8, each of the pixels PXL (or the first, second, and third sub-pixels SPX1, SPX2, and SPX3) may include an emission component EMU generating light of a luminance corresponding to a data signal, and a pixel circuit PXC for driving the emission component EMU.

The emission component EMU may include the light emitting element LD connected between a first power line PL1 receiving a voltage of first driving power VDD and a second power line PL2 receiving a voltage of second driving power VSS. For example, the emission component EMU may include the first electrode EL1 connected to the first driving power VDD via the pixel circuit PXC and the first power line PL1, and the second electrode EL2 connected to the second driving power VSS via the second power line PL2. The first electrode EL1 may be an anode, and the second electrode EL2 may be a cathode. A potential difference between the first driving power VDD and the second driving power VSS may be set to be higher than or equal to a threshold voltage of the light emitting element LD during a light emitting period of the pixel PXL.

In case that the pixel PXL (or one of the first, second, and third sub-pixels SPX1, SPX2, and SPX3) is positioned in the i-th pixel row and the j-th pixel column in the display area DA, the pixel circuit PXC of the pixel PXL (or one of the first, second, and third sub-pixels SPX1, SPX2, and SPX3) may be electrically connected to an i-th scan line Si and a j-th data line Dj. For example, the pixel circuit PXC may be electrically connected to an i-th control line CLi and a j-th sensing line SENj.

The pixel circuit PXC may include first to third transistors T1, T2, and T3 and a storage capacitor Cst.

The first transistor T1 may be a driving transistor for controlling a driving current applied to the light emitting element LD, and may be electrically connected between the first driving power VDD and the light emitting element LD. The first transistor T1 may control an amount of a driving current applied from the first driving power VDD to the light emitting element LD through a second node N2 according to a voltage applied to a first node N1.

The second transistor T2 may be a switching transistor selecting and activating the pixel PXL in response to a scan signal, and may be electrically connected between the j-th data line Dj and the first node N1. The second transistor T2 may be turned on when a scan signal of a gate-on voltage (for example, a high level voltage) is supplied from the i-th scan line Si, to electrically connect the j-th data line Dj and the first node N1.

The third transistor T3 may obtain a sensing signal through the j-th sensing line SENj by electrically connecting the first transistor T1 to the j-th sensing line SENj, and may detect a characteristic of the pixel PXL including a threshold voltage or the like of the first transistor T1 using the sensing signal. The third transistor T3 may be an initialization transistor capable of initializing the second node N2, and may be turned on when a sensing control signal is supplied from the i-th control line CLi to supply a voltage of initialization power to the second node N2. Accordingly, the storage capacitor Cst electrically connected to the second node N2 may be initialized.

The storage capacitor Cst may include a first storage electrode electrically connected to the first node N1 and a second storage electrode electrically connected to the second node N2. The storage capacitor Cst is charged with a data voltage corresponding to the data signal supplied to the first node N1 during one frame period. Accordingly, the storage capacitor Cst may store a voltage corresponding to a difference between a voltage of a gate electrode of the first transistor T1 and a voltage of the second node N2.

In FIG. 8, an embodiment in which all of the first to third transistors T1, T2, and T3 are N-type transistors is disclosed, but is not limited thereto. For example, a structure of the pixel circuit PXC may be variously changed. For example, the pixel circuit PXC may further include at least one transistor element such as a transistor element for initializing the first node N1 and/or a transistor element for controlling a light emitting time of the light emitting element LD, or other circuit elements such as a boosting capacitor for boosting the voltage of the first node N1. For example, the pixel circuit PXC may be configured by including six transistor elements and two capacitors. According to an embodiment, the pixel circuit PXC may include seven transistor elements and two capacitors.

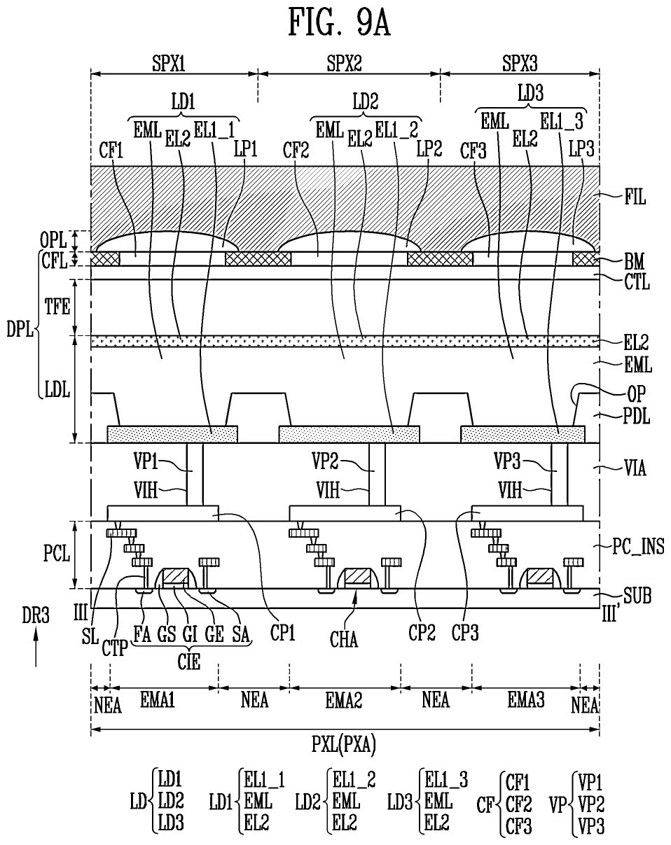

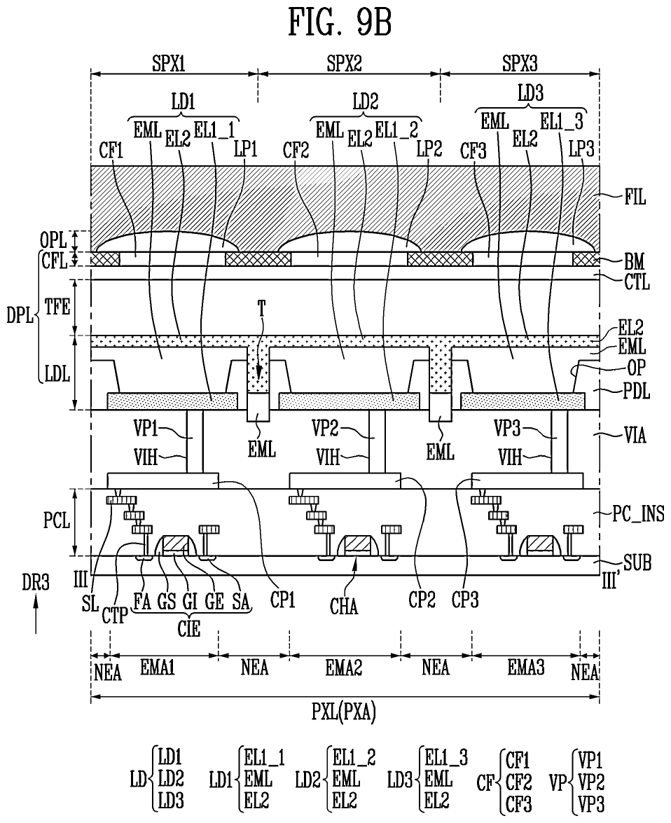

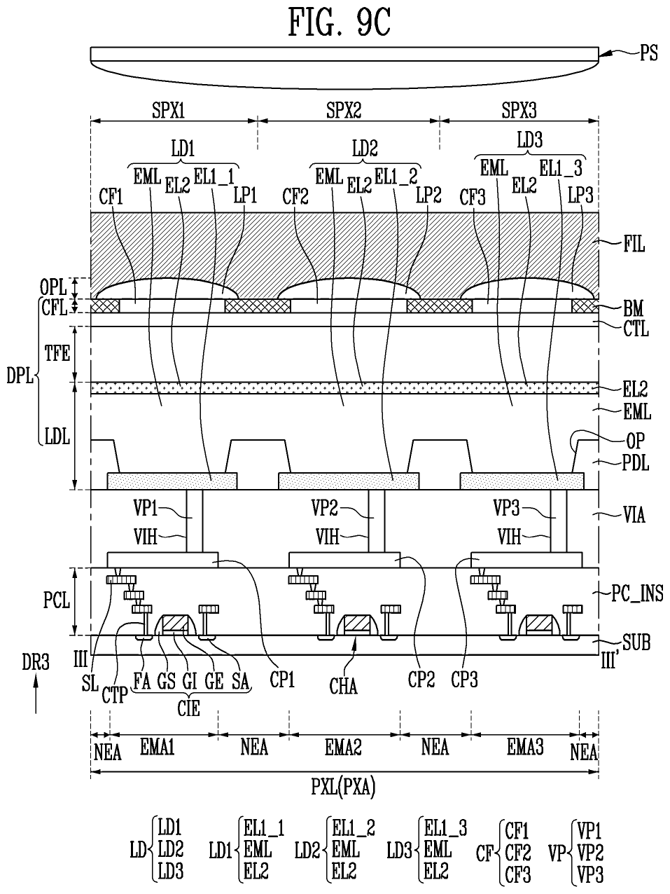

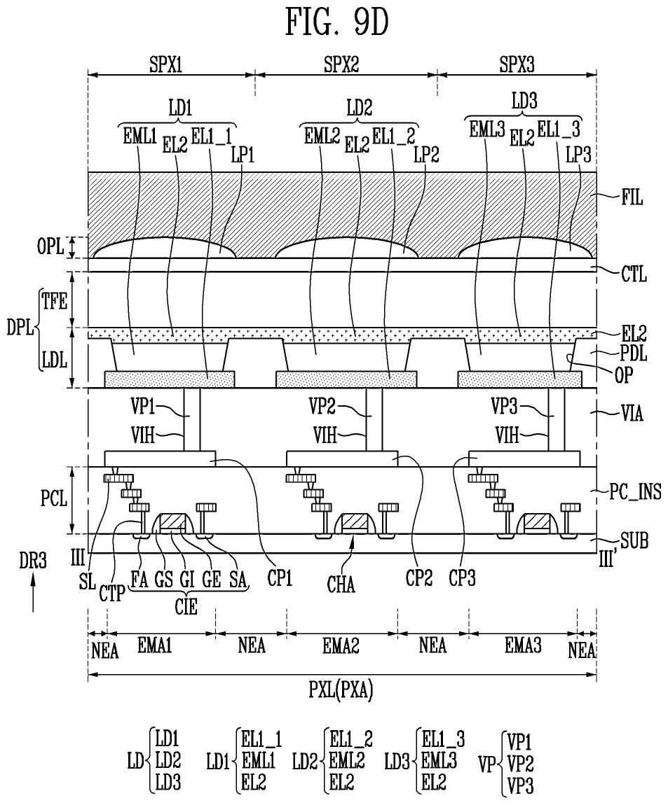

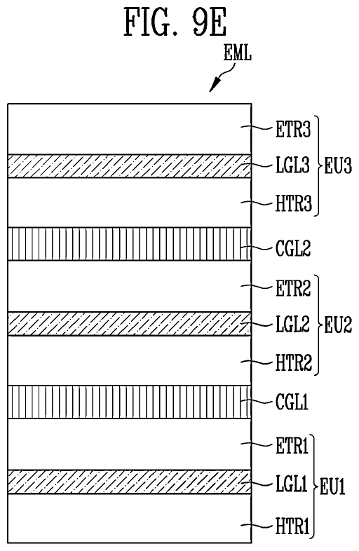

FIGS. 9A to 9D are schematic cross-sectional views taken along a line III-III′ of FIG. 5. FIG. 9E is a schematic diagram showing the light emitting layer EML of FIG. 9A.

Embodiments of FIGS. 9B to 9D illustrate modified embodiments of FIG. 9A in relation to the light emitting layer EML, the color filter layer CFL, a lens part PS, and the like.

Referring to FIGS. 5 to 9E, the pixel PXL according to an embodiment may include the first sub-pixel SPX1, the second sub-pixel SPX2, and the third sub-pixel SPX3.

Each of the first, second, and third sub-pixels SPX1, SPX2, and SPX3 may include the substrate SUB, the pixel circuit layer PCL, the via layer VIA, the display element layer DPL, the optical layer OPL, and the filling layer FIL.

The substrate SUB may include a silicon wafer substrate formed using a semiconductor process. The substrate SUB may include a semiconductor material, for example, a Group IV semiconductor, a III-V compound semiconductor, or a II-VI compound semiconductor. For example, the Group IV semiconductor may include silicon, germanium, or silicon-germanium.

The pixel circuit layer PCL may be disposed on the substrate SUB. The pixel circuit layer PCL may include a circuit element CIE, a circuit insulating layer PC_INS, a contact plug CTP, and a circuit line SL.

The circuit element CIE may include a transistor (for example, a driving transistor). The circuit element CIE may include a gate insulating layer Gl, a gate electrode GE, and a gate spacer GS. First and second areas FA and SA may be disposed in the substrate SUB at both sides of the gate electrode GE. One of the first and second areas FA and SA may be a source area, and the other may be a drain area.

The gate insulating layer Gl may be disposed on the substrate SUB. The gate insulating layer Gl may include an oxide, a nitride, or a high dielectric constant (high-k) material. A high dielectric material may refer to a dielectric material having a dielectric constant higher than that of silicon oxide (SiOx). The gate electrode GE may be disposed on the gate insulating layer Gl.

The gate electrode GE may include a conductive material. The conductive material may include, for example, a metal nitride such as titanium nitride (TiN), tantalum nitride (TaN), or tungsten nitride (WN), a metal material such as aluminum (Al), tungsten (W), copper (Cu), or molybdenum (Mo), and/or a semiconductor material such as doped polysilicon. The gate electrode GE may be formed as a single layer or multiple layers of double or more layers.

The gate spacer GS may be disposed on both side surfaces of the gate electrode GE, and may insulate the first and second areas FA and SA from the gate electrode GE. The gate spacer GS may be formed as a multiple layer structure according to an embodiment. The gate spacer GS may be formed of oxide, nitride, and oxynitride, and may be formed of, for example, a low dielectric constant layer.

The first and second areas FA and SA may be disposed in the substrate SUB at both sides of the gate electrode GE. The first and second areas FA and SA may be a semiconductor layer including silicon and may include impurities of different types and/or concentrations.

A channel area CHA may be disposed in the substrate SUB under the gate electrode GE. The channel area CHA may be connected to the first and second areas FA and SA. The channel area CHA may be formed of a semiconductor material, and may include, for example, at least one of silicon, silicon germanium, and germanium.

The contact plugs CTP may recess and contact the first and second areas FA and SA, and may be disposed along an upper surface of the first and second areas FA and SA to contact the upper surface of the first and second areas FA and SA, but are not limited thereto. The contact plugs CTP may include, for example, a metal nitride such as titanium nitride, tantalum nitride, or tungsten nitride, and/or a metal material such as aluminum, tungsten, copper, or molybdenum, but are not limited thereto.

The circuit insulating layer PC_INS may be disposed on the circuit elements CIE on the substrate SUB. The contact plug CTP may be electrically connected to the first and second areas FA and SA by passing through the circuit insulating layer PC_INS. The first and second areas FA and SA and the contact plug CTP may be electrically connected. The circuit lines SL may be electrically connected to the contact plug CTP and may be disposed as a plurality of layers.

The pixel circuit layer PCL may further include scan lines and data lines disposed to cross the scan lines.

A transistor configured by the circuit elements CIE may be electrically connected to a first electrode of a corresponding sub-pixel. For example, a transistor configured by the circuit elements CIE in the first sub-pixel SPX1 may be electrically connected to a (1-1)-th electrode EL1_1, a transistor configured by the circuit elements CIE in the second sub-pixel SPX2 may be electrically connected to a (1-2)-th electrode EL1_2, and a transistor configured by the circuit elements CIE in the third sub-pixel SPX3 may be electrically connected to a (1-3)-th electrode EL1_3.

On the pixel circuit layer PCL, first, second, and third conductive patterns CP1, CP2, and CP3 may be disposed spaced apart from each other. The first, second, and third conductive patterns CP1, CP2, and CP3 may be simultaneously or successively formed in the same process, but are not limited thereto.

The first conductive pattern CP1 may be disposed on the circuit insulating layer PC_INS in the first sub-pixel SPX1 and may be electrically connected to the transistor. For example, the first conductive pattern CP1 may be electrically connected to the circuit element CIE configuring the transistor through the corresponding circuit line SL.

The second conductive pattern CP2 may be disposed on the circuit insulating layer PC_INS in the second sub-pixel SPX2 and may be electrically connected to the transistor. For example, the second conductive pattern CP2 may be electrically connected to the circuit element CIE configuring the transistor through the corresponding circuit line SL.

The third conductive pattern CP3 may be disposed on the circuit insulating layer PC_INS in the third sub-pixel SPX3 and may be electrically connected to the transistor. For example, the third conductive pattern CP3 may be electrically connected to the circuit element CIE configuring the transistor through the corresponding circuit line SL.

The first, second, and third conductive patterns CP1, CP2, and CP3 may be utilized as a reflective member that reflects the light emitted from the light emitting layer EML and proceeding to the pixel circuit layer PCL in an upper direction (for example, in the third direction DR3). The first, second, and third conductive patterns CP1, CP2, and CP3 may include a metal material having high reflectance. For example, the first, second, and third conductive patterns CP1, CP2, and CP3 may include a material such as aluminum or silver, but are not limited thereto.

The via layer VIA may be disposed on the first, second, and third conductive patterns CP1, CP2, and CP3. The via layer VIA may cover the first, second, and third conductive patterns CP1, CP2, and CP3 and may cover the circuit insulating layer PC_INS between adjacent conductive patterns. According to an embodiment, the via layer VIA may be utilized as a planarization layer for mitigating a step difference due to configurations disposed thereunder, but is not limited thereto.

According to an embodiment, the via layer VIA may have a micro cavity structure in which the light emitted from the light emitting layer EML is reflected and re-reflected between metal patterns disposed to be spaced apart from each other vertically. The via layer VIA may include a material having high transmittance. For example, the via layer VIA may be an inorganic insulating layer including an inorganic material or an organic insulating layer including an organic material. The via layer VIA may be partially opened to include a via hole VIH exposing one area of each of the first, second, and third conductive patterns CP1, CP2, and CP3.

A via plug VP may be disposed in the via hole VIH. The via plug VP may include first, second, and third via plugs VP1, VP2, and VP3. Each of the first, second, and third via plugs VP1, VP2, and VP3 may include a conductive material such as tungsten or copper used in a semiconductor process, but is not limited thereto.

The first via plug VP1 may be electrically connected to the first conductive pattern CP1 by passing through the via layer VIA in the first sub-pixel SPX1. For example, the first via plug VP1 may be electrically connected to the (1-1)-th electrode EL1_1 of the light emitting element layer LDL.

The second via plug VP2 may be electrically connected to the second conductive pattern CP2 by passing through the via layer VIA in the second sub-pixel SPX2. For example, the second via plug VP2 may be electrically connected to the (1-2)-th electrode EL1_2 of the light emitting element layer LDL.

The third via plug VP3 may be electrically connected to the third conductive pattern CP3 by passing through the via layer VIA in the third sub-pixel SPX3. For example, the third via plug VP3 may be electrically connected to the (1-3)-th electrode EL1_3 of the light emitting element layer LDL.

According to an embodiment, the via layer VIA may be omitted. In this case, the light emitting element layer LDL may be directly disposed on the pixel circuit layer PCL.

The display element layer DPL may be disposed on the via layer VIA. The display element layer DPL may include the light emitting element layer LDL, the thin film encapsulation layer TFE, and the color filter layer CFL. According to an embodiment, the display element layer DPL may include only the light emitting element layer LDL and the thin film encapsulation layer TFE without the color filter layer CFL as shown in FIG. 9D.

The light emitting element layer LDL may include the light emitting element LD and the pixel defining layer PDL. The light emitting element LD may include a first light emitting element LD1 positioned in the first sub-pixel SPX1, a second light emitting element LD2 positioned in the second sub-pixel SPX2, and a third light emitting element LD3 positioned in the third sub-pixel SPX3. The first light emitting element LD1 may include the (1-1)-th electrode EL1_1, the light emitting layer EML, and the second electrode EL2. The second light emitting element LD2 may include the (1-2)-th electrode EL1_2, the light emitting layer EML, and the second electrode EL2. The third light emitting element LD3 may include the (1-3)-th electrode EL1_3, the light emitting layer EML, and the second electrode EL2.

Each of the (1-1)-th electrode EL1_1, the (1-2)-th electrode EL1_2, and the (1-3)-th electrode EL1_3 may be provided and/or formed on the via layer VIA of a corresponding sub-pixel. The (1-1)-th electrode EL1_1, the (1-2)-th electrode EL1_2, and the (1-3)-th electrode EL1_3 may be disposed spaced apart from each other on the via layer VIA. The (1-1)-th EL1_1 may be an anode of the first light emitting element LD1, the (1-2)-th electrode EL1_2 may be an anode of the second light emitting element LD2, and the (1-3)-th electrode EL1_3 may be an anode of the third light emitting element LD3.

The (1-1)-th, (1-2)-th, and (1-3)-th electrodes EL1_1, EL1_2, and EL1_3 may include a transparent conductive material capable of transmitting light. For example, the transparent conductive material may include a conductive oxide such as indium tin oxide (ITO), indium zinc oxide (IZO), zinc oxide (ZnOx), indium gallium zinc oxide (IGZO), indium tin zinc oxide (ITZO), a conductive polymer such as poly(3,4-ethylenedioxythiophene) (PEDOT), and the like, but is not limited thereto. According to an embodiment, the (1-1)-th, (1-2)-th, and (1-3)-th electrodes EL1_1, EL1_2, and EL1_3 may include an opaque conductive material capable of reflecting light in an upper direction.

The pixel defining layer PDL may be disposed on the (1-1)-th electrode EL1_1, the (1-2)-th electrode EL1_2, the (1-3)-th electrode EL1_3, and the via layer VIA.

The pixel defining layer PDL may be positioned in the non-emission area NEA, and may be partially opened to include an opening OP exposing one area of the (1-1)-th electrode EL1_1 in at least a first emission area EMA1, another opening OP exposing one area of the (1-2)-th electrode EL1_2 in at least a second emission area EMA2, and a still another opening OP exposing one area of the (1-3)-th electrode EL1_3 in at least a third emission area EMA3.

The pixel defining layer PDL may be formed of an organic insulating layer including an organic material. According to an embodiment, the pixel defining layer PDL may include a light absorbing material or may be coated with a light absorbing material to absorb light introduced from the outside. For example, the pixel defining layer PDL may include a carbon-based black pigment, but is not limited thereto.

The pixel defining layer PDL may protrude in the third direction DR3 from a surface (or an upper surface) of the via layer VIA.

According to an embodiment, a trench T may be provided in the pixel defining layer PDL as shown in FIG. 9B. The trench T may be formed to pass through the pixel defining layer PDL and dig up to a portion of the via layer VIA, but is not limited thereto. The trench T may expose one area of the via layer VIA between the (1-1)-th electrode EL1_1 and the (1-2)-th electrode EL1_2 and one area of the via layer VIA between the (1-2)-th electrode EL1_2 and the (1-3)-th electrode EL1_3.

The light emitting layer EML may be disposed on the (1-1)-th electrode EL1_1 exposed by the opening OP of the pixel defining layer PDL, the (1-2)-th electrode EL1_2 exposed by another opening OP of the pixel defining layer PDL, and the (1-3)-th electrode EL1-3 exposed by still another opening OP of the pixel defining layer PDL.

The light emitting layer EML may be disposed on the (1-1)-th, (1-2)-th, and (1-3)-th electrodes EL1_1, EL1_2, and EL1_3 exposed by the opening OP of the pixel defining layer PDL. For example, the light emitting layer EML may be disposed on a side surface and an upper surface of the pixel defining layer PDL. The light emitting layer EML may be a common layer commonly provided to the first, second, and third sub-pixels SPX1, SPX2, and SPX3.

The light emitting layer EML may have a multilayer thin film structure including a light generation layer that generates light. For example, the light emitting layer EML may include a hole injection layer that injects a hole, a hole transport layer having excellent hole transportability and suppressing a movement of an electron that is not combined in the light generation layer to increase a chance of recombination of a hole and an electron, the light generation layer emitting light by recombination of the injected electron and hole, a hole blocking layer for suppressing a movement of a hole that is not combined in the light generation layer, an electron transport layer for smoothly transporting the electron to the light generation layer, an electron injection layer injecting the electron, and the like, but is not limited thereto.

In an embodiment, the light emitting layer EML may emit white light. As shown in FIG. 9E, the light emitting layer EML may have a three-stack tandem light emitting structure. For example, the light emitting layer EML may include a first light emitting structure EU1, a second light emitting structure EU2, and a third light emitting structure EU3. Each light emitting layer EML of the three-stack tandem light emitting structure may include the light generation layer that generates light according to an applied current. For example, the first light emitting structure EU1 may include a first light generation layer LGL1, a first electron transport area ETR1, and a first hole transport area HTR1. The first light generation layer LGL1 may be disposed between the first electron transport area ETR1 and the first hole transport area HTR1. The second light emitting structure EU2 may include a second light generation layer LGL2, a second electron transport area ETR2, and a second hole transport area HTR2. The second light generation layer LGL2 may be disposed between the second electron transport area ETR2 and the second hole transport area HTR2. The third light emitting structure EU3 may include a third light generation layer LGL3, a third electron transport area ETR3, and a third hole transport area HTR3. The third light generation layer LGL3 may be disposed between the third electron transport area ETR3 and the third hole transport area HTR3.

Each of the first hole transport area HTR1, the second hole transport area HTR2, and the third hole transport area HTR3 may include at least one of a hole injection layer and a hole transport layer, and may further include a hole buffer layer, an electron blocking layer, and the like as occasion demands. The first hole transport area HTR1, the second hole transport area HTR2, and the third hole transport area HTR3 may have configurations equal to or different from each other.

Each of the first electron transport area ETR1, the second electron transport area ETR2, and the third electron transport area ETR3 may include at least one of an electron injection layer and an electron transport layer, and may further include an electron buffer layer, a hole blocking layer, and the like as occasion demands. The first electron transport area ETR1, the second electron transport area ETR2, and the third electron transport area ETR3 may have configurations equal to or different from each other.

A first connection layer CGL1 may be disposed between the first light emitting structure EU1 and the second light emitting structure EU2. A second connection layer CGL2 may be disposed between the second light emitting structure EU2 and the third light emitting structure EU3.

The first light generation layer LGL1, the second light generation layer LGL2, and the third light generation layer LGL3 may generate light of different colors. Light emitted from each of the first light generation layer LGL1, the second light generation layer LGL2, and the third light generation layer LGL3 may be mixed to generate white light. For example, the first light generation layer LGL1 may generate blue light, the second light generation layer LGL2 may generate green light, and the third light generation layer LGL3 may generate red light, but the disclosure is not limited thereto. According to an embodiment, the first light generation layer LGL1 and the third light generation layer LGL3 may generate blue light, and the second light generation layer LGL2 may generate yellow light. The second light generation layer LGL2 may further include a sub-light generation layer to improve purity.

In the above-described embodiment, the light emitting layer EML is the 3-stack tandem light emitting structure, but is not limited thereto. According to an embodiment, the light emitting layer EML may have a single light emitting structure or a two-stack tandem light emitting structure.

As in the embodiment shown in FIG. 9B, in case that the pixel defining layer PDL includes the trench T, the light emitting layer EML commonly provided to the first to third sub-pixels SPX1, SPX2, and SPX3 may be formed on each of the (1-1)-th, (1-2)-th, and (1-3)-th electrodes EL1_1, EL1_2, and EL1_3 and may be formed inside the trench T. As the light emitting layer EML is formed inside the trench T, the light emitting layer EML formed on each of the (1-1)-th, (1-2)-th, and (1-3)-th electrodes EL1_1, EL1_2, and EL1_3 and the light emitting layer EML formed inside the trench T may be disconnected without being connected. In particular, the first and second connection layers CGL1 and CGL2, e.g., see FIG. 9E, included in the light emitting layer EML of each sub-pixel may be disconnected without being connected to the first and second connection layers CGL1 and CGL2 included in the light emitting layer EML of an adjacent sub-pixel. In this case, transferal of a leakage current through the light emitting layer EML to the pixel PXL may be reduced or minimized, and thus reliability of each sub-pixel may be further improved.

The second electrode EL2 may be disposed on the light emitting layer EML. The second electrode EL2 may be a common layer commonly provided to the first, second, and third sub-pixels SPX1, SPX2, and SPX3. The second electrode EL2 may be provided in a plate shape over the entire area of the display area DA.

The second electrode EL2 may be a thin metal layer having a thickness sufficient to transmit the light emitted from the light emitting layer EML of each of the first, second, and third sub-pixels SPX1, SPX2, and SPX3. The second electrode EL2 may be formed of a metal material or a transparent conductive material to have a relatively thin thickness. For example, the second electrode EL2 may be formed of various transparent conductive materials. The second electrode EL2 may include at least one of various transparent conductive materials including indium tin oxide, indium zinc oxide, indium tin zinc oxide, aluminum zinc oxide, gallium zinc oxide, zinc tin oxide, or gallium tin oxide, and may be implemented as substantially transparent or translucent to satisfy a predetermined light transmittance. Accordingly, the light emitted from the light emitting layer EML positioned under the second electrode EL2 may pass through the second electrode EL2 and may be emitted in an upper direction of the thin film encapsulation layer TFE.

The thin film encapsulation layer TFE may be provided and/or formed on the entire surface of the second electrode EL2.

The thin film encapsulation layer TFE may be a shape of an encapsulation film formed of multiple layers. The thin film encapsulation layer TFE may include an inorganic layer and/or an organic layer. For example, the thin film encapsulation layer TFE may have a shape in which an inorganic layer, an organic layer, and an inorganic layer are sequentially stacked. The thin film encapsulation layer TFE may prevent external air and moisture from penetrating into the light emitting element layer LDL and the pixel circuit layer PCL.

An intermediate layer CTL may be disposed on the thin film encapsulation layer TFE.

The intermediate layer CTL may be positioned between the thin film encapsulation layer TFE and the color filter layer CFL, and may be a transparent viscosity layer (or adhesive layer), for example, an optically clear adhesive for enhancing adhesion between the thin film encapsulation layer TFE and the color filter layer CFL, but is not limited thereto. For example, the intermediate layer CTL may be formed of an insulating material having insulating and adhesive properties to protect the thin film encapsulation layer TFE. The intermediate layer CTL may be omitted according to an embodiment.

The color filter layer CFL may be disposed on the intermediate layer CTL. The color filter layer CFL may include a color filter CF and a light blocking pattern BM.

The light blocking pattern BM may be positioned to correspond to the pixel defining layer PDL on one surface of the thin film encapsulation layer TFE. The light blocking pattern BM may include a light blocking material. For example, the light blocking pattern BM may be a black matrix. The light blocking pattern BM may be configured to include at least one light blocking material and/or reflective material.

The color filter CF may include a first color filter CF1, a second color filter CF2, and a third color filter CF3. The first color filter CF1 may be disposed in the first sub-pixel SPX1, the second color filter CF2 may be disposed in the second sub-pixel SPX2, and the third color filter CF3 may be disposed in the third sub-pixel SPX3. Each of the first, second, and third color filters CF1, CF2, and CF3 may include a colorant such as a dye or pigment that absorbs a wavelength other than a corresponding color wavelength. The first color filter CF1 may be a red color filter, the second color filter CF2 may be a green color filter, and the third color filter CF3 may be a blue color filter. In the drawing, a case in which neighboring color filters CF are disposed to be spaced apart from each other with the light blocking pattern BM interposed therebetween is illustrated, but the neighboring color filters CF may overlap at least partially on the light blocking pattern BM.

According to an embodiment, the first color filter CF1, the second color filter CF2, and the third color filter CF3 disposed to overlap each other in the non-emission area NEA of each sub-pixel may be utilized as a light blocking member blocking light interference between adjacent sub-pixels instead of the light blocking pattern BM.

According to an embodiment, the light blocking pattern BM may be omitted. In this case, each of the first color filter CF1, the second color filter CF2, and the third color filter CF3 may be disposed on one surface of the thin film encapsulation layer TFE (or the intermediate layer CTL) to be in contact with each other without being spaced apart and overlapped with an adjacent color filter. For example, one end (or a first end) of the second color filter CF2 may contact one end of the first color filter CF1 on one surface of the thin film encapsulation layer TFE, and another end (or a second end) of the second color filter CF2 may contact one end of the third color filter CF3 on one surface of the thin film encapsulation layer TFE.

In the above-described embodiment, the light emitting layer EML is commonly provided to the first, second, and third sub-pixels SPX1, SPX2, and SPX3, and the different color filters CF are disposed in the first to third sub-pixels SPX1, SPX2, and SPX3, but the disclosure is not limited thereto. According to an embodiment, as shown in FIG. 9D, the first light emitting element LD1 including a first light emitting layer EML1 may be positioned in the first sub-pixel SPX1, the second light emitting element LD2 including a second light emitting layer EML2 may be positioned in the second sub-pixel SPX2, and the third light emitting element LD3 including a third light emitting layer EML3 may be positioned in the third sub-pixel SPX3. Each of the first, second, and third light emitting layers EML1, EML2, and EML3 may emit light of different colors. For example, the first light emitting layer EML1 may emit red light, the second light emitting layer EML2 may emit green light, and the third light emitting layer EML3 may emit blue light. As the red light is emitted from the first light emitting element LD1 including the first light emitting layer EML1, the green light is emitted from the second light emitting element LD2 including the second light emitting layer EML2, and the blue light is emitted from the third light emitting element LD3 including the third light emitting layer EML3, the color filter layer CFL described with reference to FIG. 9A may be omitted in the embodiment of FIG. 9D.

The optical layer OPL may be disposed on the display element layer DPL. The optical layer OPL may include a low refractive layer that changes a path of light lost among the light emitted from the light emitting element layer LDL to the front surface direction (or an image display direction of the display device DD) by using a difference in refractive index to improve a luminance of front surface light emission. For example, the optical layer OPL may include a micro lens array improving light extraction effect by changing a proceeding angle of the light emitted from the light emitting element layer LDL by forming a micro lens of a specific shape such as a hemispherical shape on a surface of the display element layer DPL.

In case that the optical layer OPL includes the micro lens array, the optical layer OPL may include a first lens LP1, a second lens LP2, and a third lens LP3. The first lens LP1 may be disposed on the first color filter CF1, the second lens LP2 may be disposed on the second color filter CF2, and the third lens LP3 may be disposed on the third color filter CF3. A distance between the first, second, and third lenses LP1, LP2, and LP3 may be set substantially equal to a distance between the sub-pixels. Accordingly, one lens may be disposed to correspond to one sub-pixel. In this case, the first to third lenses LP1, LP2, and LP3 may be formed so that all focal lengths are the same, but are not limited thereto. According to an embodiment, the distance between the first, second, and third lenses LP1, LP2, and LP3 may be set different from the distance between the sub-pixels in order to adjust a viewing angle toward an outside of the display device DD (or the display panel DP). For example, each of the first, second, and third lenses LP1, LP2, and LP3 may not be disposed only on the corresponding color filter CF in the third direction DR3 (or a vertical direction). For example, the first lens LP1 may not be disposed only on the first color filter CF1, and may be disposed over the first color filter CF1 and the adjacent color filters CF of the first color filter CF1, or may be disposed only on the adjacent color filter CF. The second lens LP2 may not be disposed only on the second color filter CF2, and may be disposed over the second color filter CF2 and the adjacent color filter CF (for example, the first color filter CF1 or the third color filter CF3) of the second color filter CF2, or may be disposed only on the adjacent color filter CF. The third lens LP3 may not be disposed only on the third color filter CF3, and may be disposed over the third color filter CF3 and the adjacent color filter CF of the third color filter CF3, or may be disposed only on the adjacent color filter CF. That is, each of the first, second, and third lenses LP1, LP2, and LP3 may not be directly disposed on the corresponding color filter CF in the vertical direction, and may be shifted with the corresponding color filter CF and disposed.

The filling layer FIL may be disposed on the optical layer OPL. The filling layer FIL may be disposed on the optical layer OPL in the display area DA to cover a lower member including the optical layer OPL. The filling layer FIL may prevent moisture or oxygen from entering the lower members.

In case that the above-described display device DD is applied to a device or the like for implementing virtual reality (VR), referring to FIG. 9C, the lens part PS may be disposed on the display device DD. The lens part PS may include a pancake lens adopting a reflective polarization method to reduce a distance between the display device DD and the lens part PS, but is not limited thereto. According to an embodiment, the lens part PS may include a polarization layer.

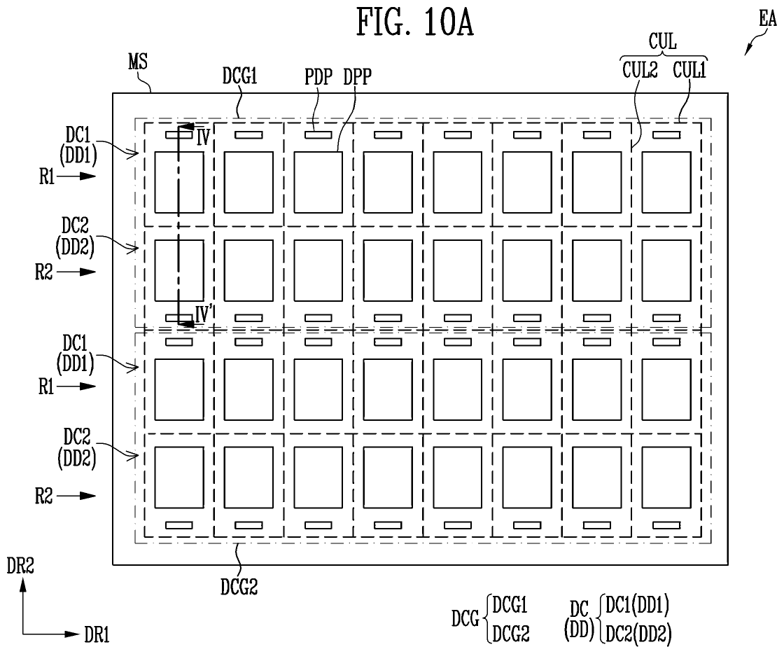

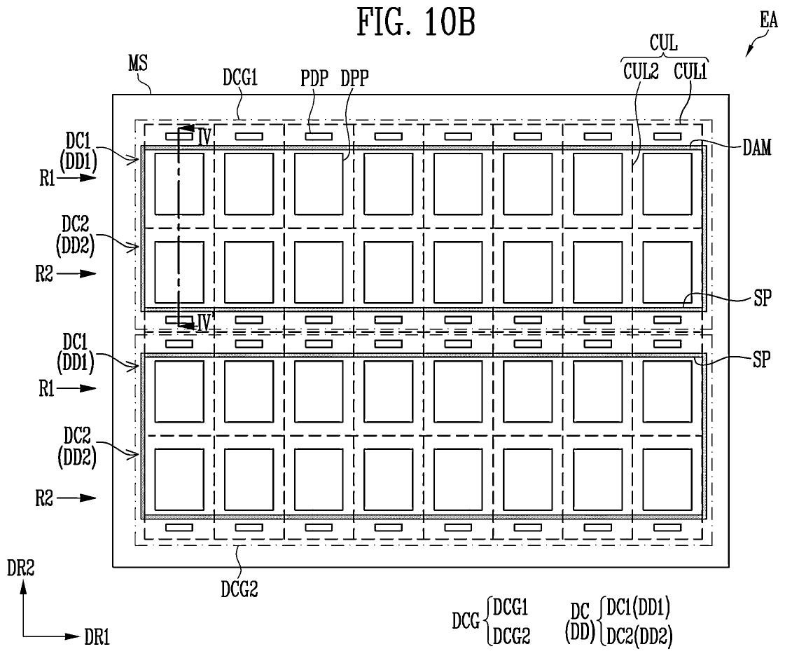

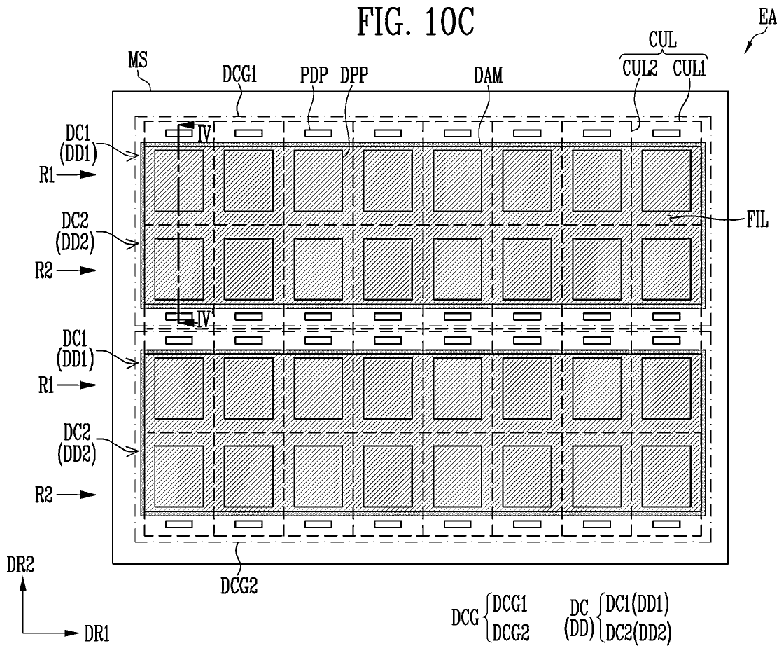

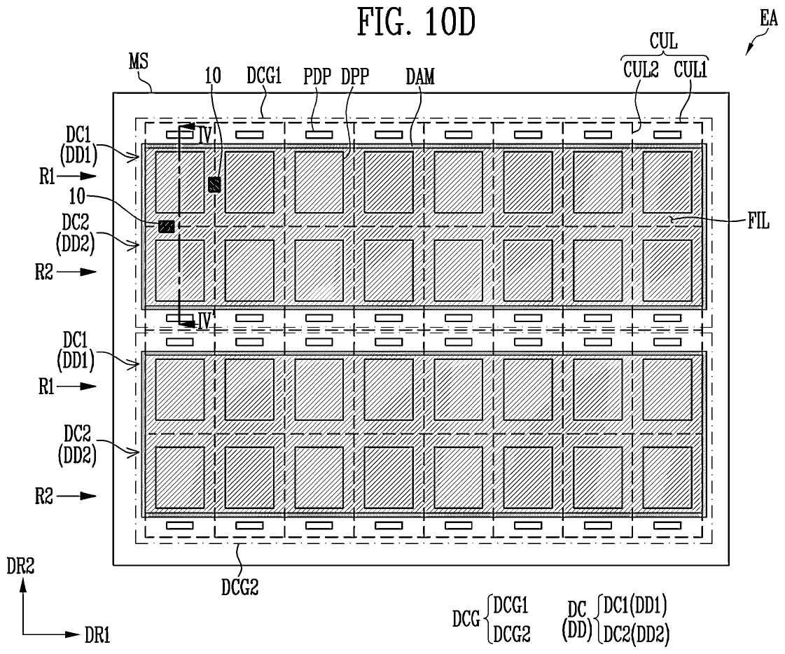

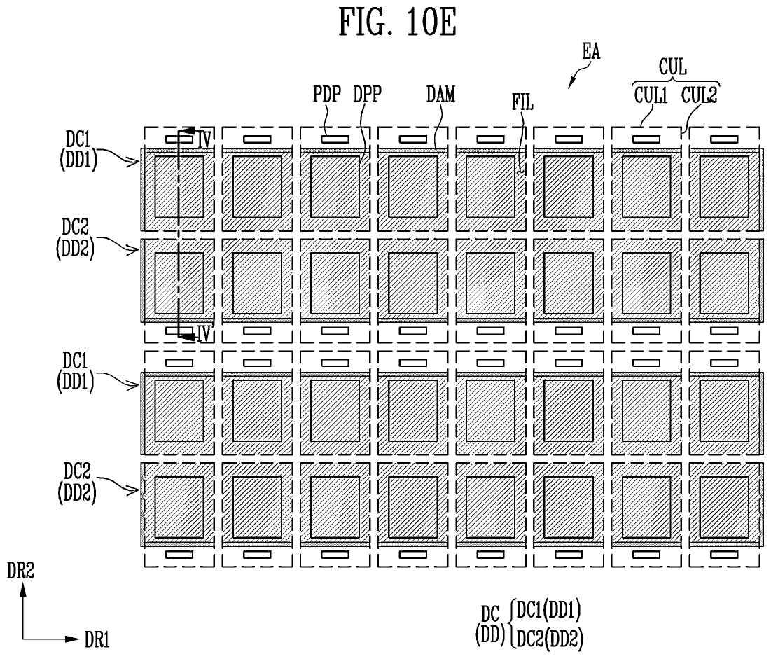

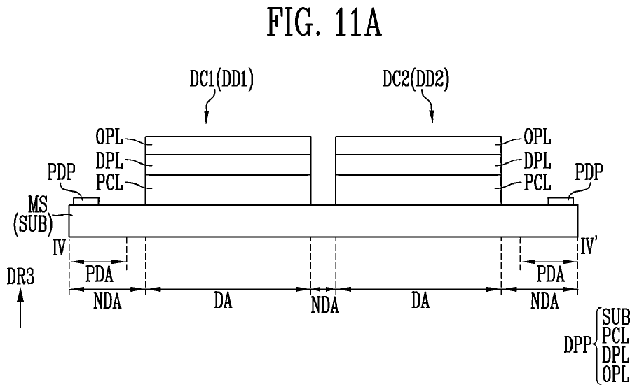

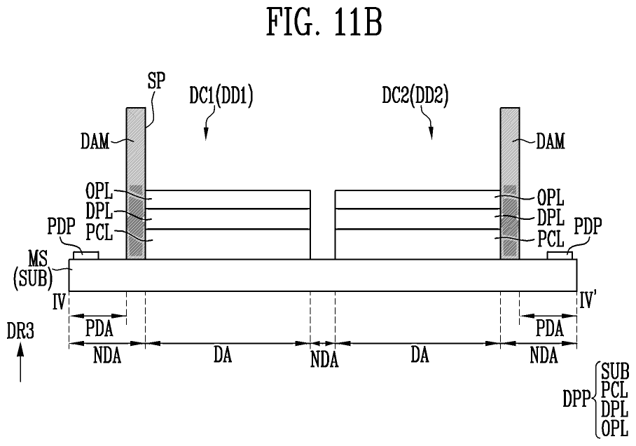

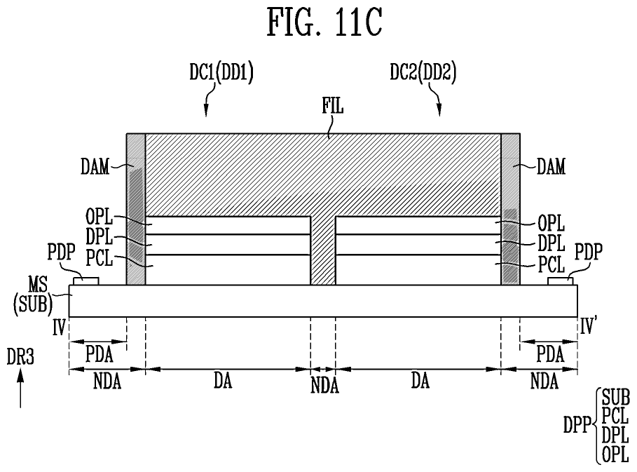

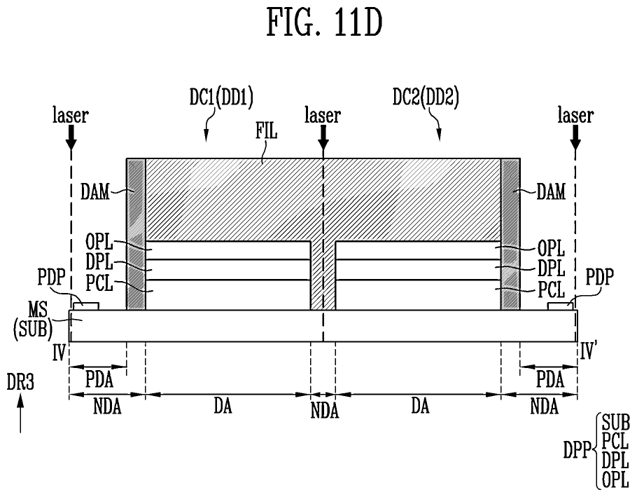

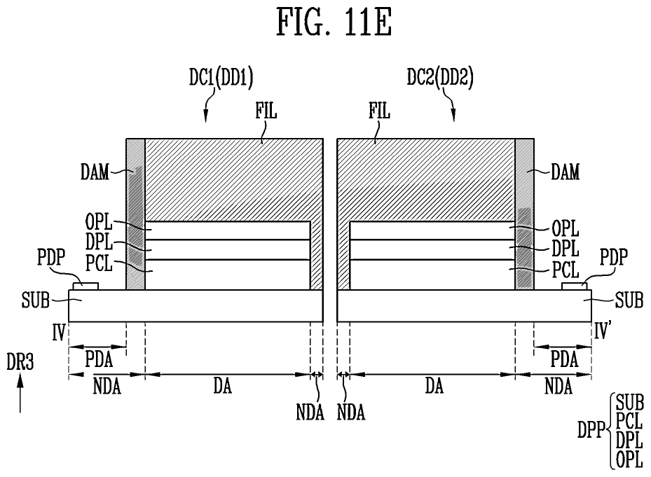

FIGS. 10A to 10E are schematic plan views corresponding to the EA portion of FIG. 1 sequentially illustrating a method of manufacturing a display device DD according to an embodiment. FIG. 11A is a schematic cross-sectional view taken along a line IV-IV′ of FIG. 10A. FIG. 11B is a schematic cross-sectional view taken along the line IV-IV′ of FIG. 10B. FIG. 11C is a schematic cross-sectional view taken along the line IV-IV′ of FIG. 10C. FIG. 11D is a schematic cross-sectional view taken along the line IV-IV′ of FIG. 10D. FIG. 11E is a schematic cross-sectional view taken along the line IV-IV′ of FIG. 10E.

In an embodiment of FIGS. 10A to 11E, manufacturing steps of the display device DD are described as being sequentially performed, but unless the concept or the like of the disclosure is changed, it is obvious that some steps shown as being performed in succession may be simultaneously performed, an order of each step may be changed, some steps may be omitted, or another step may be further included between each step.

In FIGS. 10A to 11E, in order to avoid an overlapping description, a point different from the above-described embodiment is mainly described.

Referring to FIGS. 1, 10A, and 11A, the plurality of display cells DC are formed on the mother substrate MS.

The mother substrate MS may include a plurality of unit areas partitioned along the cutting line CUL. Each unit area may be a portion corresponding to the display cell DC (or the display device DD), and the substrate SUB of the display cell DC (or the display device DD) may be formed for each unit area. The unit area may have the same size, but is not limited thereto.

A corresponding display cell DC is formed for each unit area. The display cell DC may include the pad part PDP and the display part DPP. The display part DPP may be disposed in the display area DA of the unit area of the mother substrate MS, and the pad part PDP may be disposed in the non-display area NDA of the unit area. In the non-display area NDA, one area where the pad part PDP is positioned may be the pad area PDA.

The first display cell group DCG1 and the second display cell group DCG2 alternately arranged in the second direction DR2 may be defined in the mother substrate MS. Each of the first display cell group DCG1 and the second display cell group DCG2 may include the plurality of first display cells DC1 and the plurality of second display cells DC2. The first display cells DC1 may be some display cells DC arranged in the first row R1, and the second display cells DC2 may be some other display cells DC arranged in the second row R2.

In the first and second display cell groups DCG1 and DCG2, the display part DPP of each first display cell DC1 may face the display part DPP of the second display cell DC2 positioned in the same column in the second direction DR2. In each of the first and second display cell groups DCG1 and DCG2, the first display cell DC1 and the second display cell DC2 positioned in the same column may be symmetrical with the first cutting line CUL1 interposed therebetween.

The pad part PDP of each of the second display cells DC2 of the first display cell group DCG1 may face the pad part PDP of the first display cell DC1 of the second display cell group DCG2 positioned in the same column. The second display cell DC2 of the first display cell group DCG1 and the first display cell DC1 of the second display cell group DCG2 positioned in the same column may be symmetrical with the first cutting line CUL1 interposed between the first display cell group DCG1 and the second display cell groupsDCG2.

Referring to FIGS. 1, 10A, 10B, 11A, and 11B, the first coating liquid is applied to surround at least one side outer periphery of the display parts DPP to include all display parts DPP in each of the first and second display cell groups DCG1 and DCG2, and then the first coating liquid is cured, to form the dam DAM.

The dam DAM may be formed by including the curable resin having the viscosity of the certain level or higher, applying the curable resin to a predetermined application area, and then curing the curable resin. For example, the dam DAM may include a light blocking material and a photocurable resin including a photopolymerization initiator that is crosslinked and cured by light such as ultraviolet rays and infrared rays. For example, the dam DAM may surround the display parts DPP in each of the first and second display cell groups DCG1 and DCG2. As the dam DAM includes the curable resin having the viscosity of at least the certain level, for example, about 160,000, the dam DAM may have the pencil hardness of 7H or more in the curing process.

As the display parts DPP are disposed to face each other in each of the first and second display cell groups DCG1 and DCG2, the dam DAM may surround at least one side of the display part DPP of each display cell DC and may be positioned between the pad part PDP and the display part DPP of the corresponding display cell DC.

In general, in the mother substrate, the plurality of display cells may be designed so that a configuration (for example, the pad part and the display part) thereof has the same arrangement. For example, each of the display cells may be formed on the mother substrate so that the display part and the pad part are sequentially arranged in the column direction or the pad part and the display part are sequentially arranged in the column direction. At this time, a dam portion is formed to surround all edges (for example, upper, lower, left, and right sides) of the display part of each of the display cells. In this case, an application area of a coating liquid corresponding to a base material of the dam portion is narrowed, and thus a defect that the coating liquid invades the display part occurs. In the above-described embodiment, since the display part DPP of the first display cell DC1 and the display part DPP of the second display cell DC2 positioned in the same column in each display cell group DCG of the mother substrate MS are arranged to face each other. Therefore, an area where the first coating liquid is applied may be secured by applying the first coating liquid in a form surrounding at least one side outer periphery of the display part DPP of each of the first and second display cells DC1 and DC2. Accordingly, the display cell DC (or the display device DD) having improved reliability may be implemented by reducing or preventing a defect caused by the first coating liquid invading the display part DPP.

In addition, in the above-described embodiment, as the dam DAM is formed by applying the first coating liquid in a form surrounding the outer periphery of the display parts DPP to include all display parts DPP in each display cell group DCG, and then curing the first coating liquid, the number of coating may be reduced compared to a case in which a dam portion is formed by applying a coating liquid in a form surrounding all edges (for example, upper, lower, left, and right sides) of the display part and then curing the coating liquid, thereby improving manufacturing efficiency of the display device DD.

Referring to FIGS. 1, 10A to 10C, and 11A to 11C, the second coating liquid is applied to an inside of a space (refer to “SP” of FIGS. 10B and 11B) surrounded by the dam DAM, and the second coating liquid is cured, to form the filling layer FIL. The second coating liquid may include a curable resin having a viscosity of a certain level or higher, for example, about 2,000, and may be cured in a curing process, to form the filling layer FIL having a pencil hardness of 4H or more.

The filling layer FIL may be positioned on the uppermost layer in the third direction DR3 in each display cell DC and may provide a display surface and/or an input surface to a user. The filling layer FIL may be a protective layer or a cover member that protects each display cell DC from external impact or the like. In each display cell group DCG, the filling layer FIL having a hardness of a certain level or higher (for example, a pencil hardness of 4H or higher) formed inside the space SP surrounded by the dam DAM may protect each display cell DC of the mother substrate MS instead of a cover glass (or an encapsulation glass) of an existing display device.

Referring to FIGS. 1, 10A to 10D, and 11A to 11D, a laser cutting device 10 is disposed on the mother substrate MS.

Referring to FIGS. 1, 10A to 10E, and 11A to 11E, the mother substrate MS is divided into the unit of each display cell DC by irradiating a laser beam from the laser cutting device 10 to correspond to the cutting line CUL.

After a cutting process using the laser beam, a process such as polishing or rounding an edge of the individually separated display cell DC may be further performed. For example, after the cutting process using the laser beam, a process of chemically strengthening the substrate SUB of each display cell DC may be further performed. For example, a cleaning process or the like of removing a foreign substance on a surface of the substrate SUB may be further performed prior to the strengthening process.

The separated display cells DC may be utilized in various electronic devices and the like such as a TV, a smart phone, and a wearable device. For example, the separated display cells DC may be utilized in a device or the like for implementing virtual reality or augmented reality (AR).

Mechanical strength of the mother substrate MS may be sufficiently improved by the dam DAM having the pencil hardness of 7H or more and the filling layer FIL having the pencil hardness of 4H or more. In this case, in the process of separating the mother substrate MS into each display cell DC unit, the filling layer FIL may provide the display surface and/or the input surface of the corresponding display cell DC while protecting the display part DPP of each display cell DC instead of an encapsulation glass (or a cover glass).

In the above-described embodiment, each display cell DC may be protected by using the filling layer FIL and the dam DAM including the curable resin instead of an encapsulation glass. Accordingly, a process of capping the encapsulation glass on the mother substrate MS may be omitted, and a process of separately cutting the encapsulation glass may be omitted in the process of separating the mother substrate MS into each display cell DC unit. Accordingly, in the above-described embodiment, a manufacturing efficiency of the display device DD may be improved.

In addition, in the above-described embodiment, as the encapsulation glass is omitted, a defect caused by a movement of a foreign substance (for example, a fragment or the like of the encapsulation glass) to the pad part PDP during cutting the encapsulation glass may be prevented, thereby preventing the pad part PDP from being damaged.

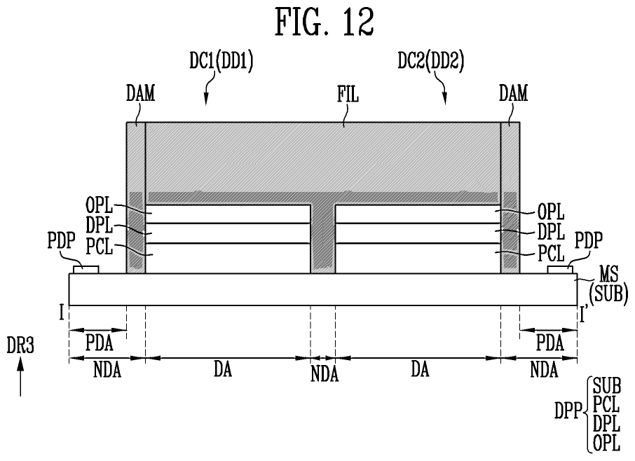

FIG. 12 is a schematic cross-sectional view corresponding to the line I-I′ of FIG. 2 illustrating the mother substrate MS according to an embodiment. In the embodiment of FIG. 12, a point different from the above-described embodiment is mainly described in order to avoid an overlapping description.

Referring to FIGS. 2 and 12, the filling layer FIL is formed in a space of the mother substrate MS surrounded by the dam DAM. The filling layer FIL may include a curable resin having the same viscosity as that of the dam DAM. For example, the filling layer FIL and the dam DAM may include a curable resin having a viscosity of about 160,000 (for example, a high viscosity).

In case that the filling layer FIL includes the curable resin of the high viscosity of the same as that of the dam DAM, the first coating liquid, which is the base material of the dam DAM, may be applied to a predetermined application area (for example, between the display part DPP and the pad part PDP of each display cell DC), and the second coating liquid, which is the base material of the filling layer FIL, may be applied in one area of the mother substrate MS surrounded by the first coating liquid, and then the first coating liquid may be cured together when the second coating liquid is cured. Therefore, the dam DAM and the filling layer FIL may be simultaneously formed. As the first coating liquid includes the curable resin of the high viscosity, since the first coating liquid is fixed to a targeted area without moving or flowing to another area after being applied to the targeted area, the first coating liquid and the second coating liquid may be cured together after applying the second coating liquid.

However, the disclosure is not limited to the above-described embodiment, and after forming the dam DAM by applying the first coating liquid to the targeted area and performing a curing process using light, the filling layer FIL may be formed by applying and curing the second coating liquid in one area of the mother substrate MS surrounded by the dam DAM.

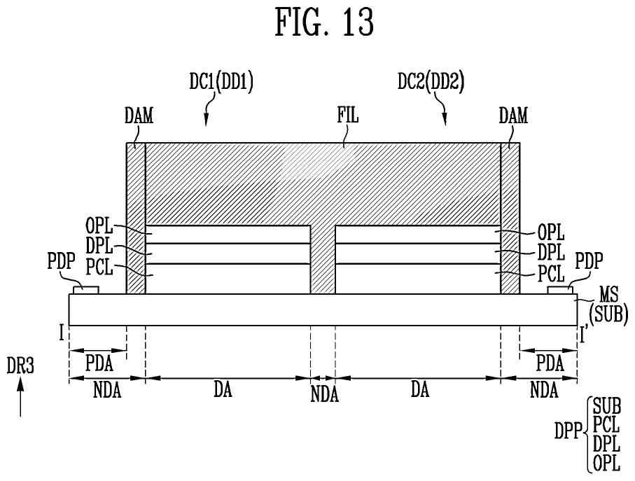

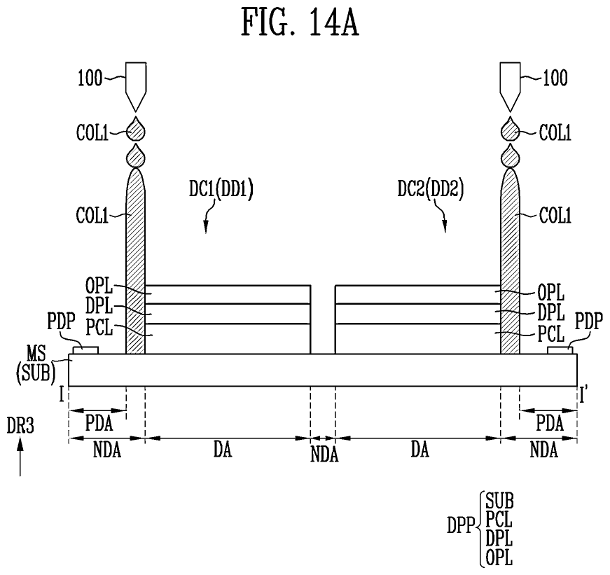

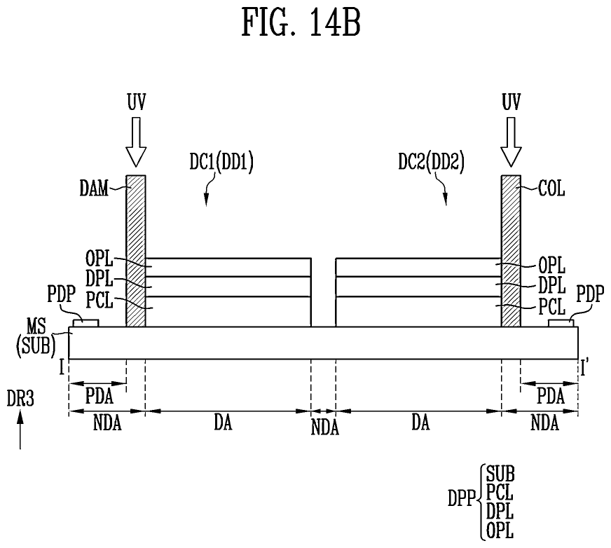

FIG. 13 is a schematic cross-sectional view corresponding to the line I-I′ of FIG. 2 illustrating a mother substrate MS according to an embodiment. FIGS. 14A and 14B are schematic cross-sectional views illustrating a manufacturing method of forming the dam DAM of FIG. 13.

In an embodiment of FIGS. 13 to 14B, a point different from the above-described embodiment is mainly described in order to avoid an overlapping description.

Referring to FIGS. 2 and 13 to 14B, a first coating liquid COL1 is applied between the pad part PDP and the display part DPP in each display cell DC of the mother substrate MS. The first coating liquid COL1 may be applied to a predetermined application area through a coating liquid supply part 100. The first coating liquid COL1 may include a curable resin having the same viscosity as that of the filling layer FIL. For example, the first coating liquid COL1 may include a curable resin having a viscosity of about 2,000 (for example, a low viscosity).

In this case, the dam DAM is formed by applying the first coating liquid COL1 to the predetermined application area and then immediately performing a light curing process using UV so that the first coating liquid COL1 does not move or flow. After the dam DAM is formed, the filling layer FIL is formed by applying the second coating liquid in one area of the mother substrate MS surrounded by the dam DAM and then curing the second coating liquid.

Although the disclosure has been described with reference to the embodiment above, those skilled in the art or those having a common knowledge in the art will understand that the disclosure may be variously modified and changed without departing from the technical area of the disclosure described in the claims which will be described later.

Therefore, the technical scope of the disclosure should not be limited to the contents described in the detailed description of the specification, but should be defined by the claims.

What is claimed is:

1. A display device comprising:
a substrate where a display area and a non-display area are defined, the non-display area including a pad area;
a display part including the substrate and displaying an image;
a pad part disposed in the pad area and including a plurality of pads;
a dam positioned between the pad part and the display part and surrounding at least one side of the display part; and
a filling layer disposed on the display part surrounded by the dam to cover the display part,
wherein the filling layer includes a transparent curable resin and is positioned in an uppermost layer in the display area.

2. The display device according to claim 1, wherein the filling layer includes at least one of epoxy and silicone, and
the dam includes a siloxane-based resin.

3. The display device according to claim 2, wherein the dam has a width of about 0.5 mm to 5 mm.

4. The display device according to claim 3, wherein the dam includes a curable resin of which a viscosity is higher than a viscosity of the filling layer.

5. The display device according to claim 3, wherein the dam and the filling layer include a curable resin of which a viscosity is the same.

6. The display device according to claim 1, wherein the substrate includes a silicon wafer substrate.

7. The display device according to claim 2, wherein the display part comprises:
a pixel circuit layer disposed on the substrate;
a light emitting element layer including a light emitting element, the light emitting element configured of a first electrode disposed on the pixel circuit layer, a light emitting layer disposed on the first electrode, and a second electrode disposed on the light emitting layer; and
a thin film encapsulation layer disposed between the light emitting element layer and the filling layer.

8. The display device according to claim 7, wherein the display part further comprises an optical layer disposed between the thin film encapsulation layer and the filling layer.

9. The display device according to claim 1, wherein the dam has a pencil hardness of 7H or more, and the filling layer has a pencil hardness of 4H or more.

10. A method of manufacturing a display device, the method comprising:
preparing a mother substrate including a first display cell group and a second display cell group including first display cells and second display cells, respectively, and a cutting line of a shape corresponding to each of the first and second display cells;
forming a dam surrounding a display part of the first and second display cells;
forming a filling layer on the display part surrounded by the dam; and
individually separating the first and second display cells by cutting the mother substrate by irradiating a laser beam,
wherein the first display cell group and the second display cell group are symmetrical with respect to the cutting line between the first display cell group and the second display cell group.

11. The method according to claim 10, wherein each of the first and second display cells includes the display part and a pad part positioned around the display part, and
the display part comprises:
a pixel circuit layer disposed on the mother substrate; and
a light emitting element layer including a light emitting element, the light emitting element configured of a first electrode disposed on the pixel circuit layer, a light emitting layer disposed on the first electrode, and a second electrode disposed on the light emitting layer.

12. The method according to claim 11, wherein in a plan view, the display part of each of the first display cells and the display part of each of the second display cells in each of the first and second display cell groups face each other in a column direction of the mother substrate.

13. The method according to claim 12, wherein in each of the first and second display cells, the dam is positioned between the display part and the pad part.

14. The method according to claim 13, wherein in each of the first and second display cell groups, the dam is coated and then cured to be formed along at least one outer periphery of the display part of each of the first and second display cells.

15. The method according to claim 14, wherein in each of the first and second display cell groups, the filling layer is coated and then cured to fill an inside of one area of the mother substrate surrounded by the dam.

16. The method according to claim 11, wherein in a plan view, the pad part of each of the second display cells of the first display cell group and the pad part of each of the first display cells of the second display cell group face each other in a column direction of the mother substrate.

17. The method according to claim 10, wherein the filling layer includes at least one of epoxy and silicone, and
the dam includes a siloxane-based resin.

18. The method according to claim 10, wherein the dam includes a curable resin of which a viscosity is higher than a viscosity of the filling layer.

19. The method according to claim 10, wherein the dam and the filling layer include a curable resin of which a viscosity is the same.

20. The method according to claim 19, wherein the dam is applied and then directly cured to be formed along at least one outer periphery of the display part of each of the first and second display cells.
